(19) United States
(12) Patent Application Publication
(10) Pub. No.: US 2025/0143043 A1
(43) Pub. Date: May 1, 2025

(54) DISPLAY DEVICE AND METHOD FOR FABRICATING THE SAME

(71) Applicant: Samsung Display Co., LTD., Yongin-si (KR)

(72) Inventors: Kyung Rock Son, Yongin-si (KR); Sun PARK, Yongin-si (KR); Hui Won YANG, Yongin-si (KR); Jae Bok YOO, Yongin-si (KR); Jae Phil LEE, Yongin-si (KR)

(21) Appl. No.: 18/888,909

(22) Filed: Sep. 18, 2024

(30) Foreign Application Priority Data
Oct. 31, 2023 (KR) 10-2023-0147810

(51) Int. Cl. H01L 33/62; H01L 25/16

(52) U.S. Cl. CPC H10H 20/857; H01L 25/167; H10H 20/0364

(57) ABSTRACT

A display device includes a substrate, first and second electrodes on the substrate, an organic pattern layer between the first electrode and the second electrode, a light emitting element on the organic pattern layer and having a first contact electrode and a second contact electrode on a top surface, a first via layer covering the first electrode and the second electrode and covering a portion of a side surface of the light emitting element, a first lower connection electrode connecting the first electrode and the first contact electrode on the first via layer, and a second lower connection electrode connecting the second electrode and the second contact electrode, a second via layer on the first via layer and covering a portion of a side surface of the light emitting element, and a first upper connection electrode connecting the first electrode and the first contact electrode.

### CROSS-REFERENCE TO RELATED APPLICATION

The present application claims priority to and the benefit of Korean Patent Application No. 10-2023-0147810, filed on Oct. 31, 2023, in the Korean Intellectual Property Office, the entire disclosure of which is incorporated by reference herein.

### BACKGROUND

### 1. Field

The present disclosure relates to a display device and a method of manufacturing the same.

### 2. Description of the Related Art

With the development of the information society, the demand for display devices for displaying images is increasing in various forms. The display device may be a flat panel display such as a liquid crystal display, a field emission display, a light emitting display, and the like. The light emitting display device may include an organic light emitting display device including an organic light emitting diode (OLED) element as a light emitting element, and a miniature light emitting display device including a micro light emitting diode element (hereinafter referred to as a micro light emitting element) as a light emitting element.

When manufacturing a micro light emitting display device, defective bonding between the light emitting element and the electrode may occur due to outgassing generated during the processing of the organic layer surrounding the micro light emitting element. As a result of this bonding failure, the micro light emitting element may not emit light.

Aspects and features of embodiments of the present disclosure provide a display device and a method of manufacturing the same that may reduce or prevent a micro light emitting element from being electrically connected to a pixel electrode or a common electrode.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes a substrate, a first electrode and a second electrode on the substrate and spaced from each other, an organic pattern layer between the first electrode and the second electrode, a light emitting element on the organic pattern layer and having a first contact electrode and a second contact electrode on a top surface, a first via layer covering the first electrode and the second electrode and covering a portion of a side surface of the light emitting element, a first lower connection electrode connecting the first electrode and the first contact electrode on the first via layer, and a second lower connection electrode connecting the second electrode and the second contact electrode, a second via layer on the first via layer and covering a portion of a side surface of the light emitting element, and a first upper connection electrode connecting the first electrode and the first contact electrode on the second via layer, and a second upper connection electrode connecting the second electrode and the second contact electrode.

In one or more embodiments, the first via layer includes a first connection hole and a second connection hole, wherein the first connection hole exposes the first electrode, and the second connection hole exposes the second electrode.

In one or more embodiments, the first lower connection electrode is in contact with the first electrode through the first connection hole, and the second lower connection electrode is in contact with the second electrode through the second connection hole.

In one or more embodiments, the second via layer includes a third connection hole and a fourth connection hole, the third connection hole exposes the first lower connection electrode connected to the first electrode, the fourth connection hole exposes the second lower connection electrode connected to the second electrode, the third connection hole and the fourth connection hole are farther from the light emitting element than the first connection hole and the second connection hole.

In one or more embodiments, the first upper connection electrode is in contact with the first lower connection electrode through the third connection hole, and the second upper connection electrode is in contact with the second lower connection electrode through the fourth connection hole.

In one or more embodiments, the first lower connection electrode is between the first contact electrode and the first upper connection electrode on the light emitting element, and the second lower connection electrode is between the second contact electrode and the second upper connection electrode on the light emitting element.

In one or more embodiments, the light emitting element includes a third semiconductor layer on the organic pattern layer, a second semiconductor layer on the third semiconductor layer, an active layer on the second semiconductor layer, a first semiconductor layer on the active layer and an element insulating layer around the light emitting element, wherein the first contact electrode and the second contact electrode are on the first semiconductor layer, the first contact electrode is connected to the first semiconductor layer, and the second contact electrode is connected to the second semiconductor layer.

In one or more embodiments, the first via layer is lower than the active layer.

In one or more embodiments, a height of the second via layer is equal to or higher than a height of the light emitting element.

In one or more embodiments, the second via layer includes a fifth connection hole overlapping the first contact electrode of the light emitting element and exposing the first lower connection electrode, and a sixth connection hole overlapping the second contact electrode and exposing the second lower connection electrode.

In one or more embodiments, the first upper connection electrode is in contact with the first lower connection electrode through the fifth connection hole, and the second upper connection electrode is in contact with the second lower connection electrode through the sixth connection hole.

In one or more embodiments, the first via layer includes a light blocking material.

In one or more embodiments, the first electrode and the second electrode are spaced from each other on the same plane and protrude outward from the light emitting element.

In one or more embodiments, the first electrode and the second electrode are spaced apart from each other at a first gap on the same plane, and the first gap is smaller than a width of the light emitting element.

In one or more embodiments, the display device further includes a reflective layer between the first electrode and the second electrode on the substrate, wherein the first electrode and the second electrode are on the same plane and spaced from each other at a first gap, and the first gap is wider than a width of the light emitting element.

In one or more embodiments, the reflective layer overlaps the light emitting element, and a width of the reflective layer is greater than the width of the light emitting element.

In one or more embodiments, a width of the organic pattern layer is greater than a width of the light emitting element.

In one or more embodiments, the organic pattern layer covers a portion of the first electrode and the second electrode and fills a gap space between the first electrode and the second electrode.

According to one or more embodiments, a method of manufacturing display device includes preparing a substrate on which a first electrode and a second electrode are located, forming an organic pattern layer between the first electrode and the second electrode on the substrate, disposing and fixing a light emitting element on the organic pattern layer, forming a first via layer covering the light emitting element and having a plurality of connection holes, and forming a first lower connection electrode connecting the first electrode and a first contact electrode located on the light emitting element through the plurality of connection holes and a second lower connection electrode connecting the second electrode and a second contact electrode located on the light emitting element on the first via layer, forming a second via layer covering a portion of a side surface of the light emitting element on the first via layer and forming a first upper connection electrode connecting the first electrode and the first contact electrode and a second upper connection electrode connecting the second electrode and the second contact electrode on the second via layer.

In one or more embodiments, the method further includes forming a partition wall including a light blocking material on the second via layer, forming a first wavelength conversion layer in an area corresponding to a first sub-pixel, forming a second wavelength conversion layer in an area corresponding to a second sub-pixel, and forming a light transmission layer in an area corresponding to a third sub-pixel from among the areas compartmentalized by the partition wall and forming a first color filter on the first wavelength conversion layer, forming a second color filter on the second wavelength conversion layer, and forming a third color filter on the light transmission layer.

According to one or more embodiments, a display device includes a substrate, a first electrode and a second electrode on the substrate and spaced from each other, an organic pattern layer overlapping at least a portion of the first electrode and the second electrode, a light emitting element on the organic pattern layer and having a first contact electrode and a second contact electrode on one surface, a first via layer on top of the first electrode and the second electrode and exposing the first contact electrode and the second contact electrode of the light emitting element, a first lower connection electrode electrically connecting the first electrode and the first contact electrode on the first via layer, and a second lower connection electrode electrically connecting the second electrode and the second contact electrode, a second via layer on top of the first via layer, and a first upper connection electrode connecting the first electrode and the first contact electrode on the second via layer, and a second upper connection electrode connecting the second electrode and the second contact electrode.

According to one or more embodiments, a display device includes a substrate, a first electrode on the substrate, an organic pattern layer partially overlapping the first electrode, a light emitting element on the organic pattern layer and having at least one first contact electrode on one surface, a first lower connection electrode on the first electrode and connecting the first electrode of the light emitting element to the first contact electrode, a second lower connection electrode on a first contact area on the first electrode and connected to the first lower connection electrode in the first contact area, and a second contact area connected to the first lower connection electrode in the second contact area, wherein the first electrode, the first lower connection electrode, and the second lower connection electrode overlap each other in the second contact area.

The display device according to one or more embodiments may reduce or minimize the possibility of a disconnection between the light emitting element and the circuit electrode, thereby reducing or minimizing a defect in the dark spot of a pixel. Furthermore, it is possible to reduce or minimize light mixing between pixels.

However, the effects, aspects, and features of embodiments of the present disclosure are not limited to the aforementioned effects, aspects, and features, and various other effects, aspects, and features are included in the present disclosure.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is a circuit diagram illustrating a first sub-pixel of a display panel according to one or more embodiments.

FIG. 5 is a circuit diagram illustrating a first sub-pixel of a display panel, according to one or more embodiments.

FIG. 6 is a layout diagram illustrating pixels of a display area according to one or more embodiments.

FIG. 7 is a cross-sectional view illustrating one example of a cross-section of the display panel corresponding to the lines I1-I1′, I2-I2′, and I3-I3′ of FIG. 6.

FIG. 8 is a cross-sectional view illustrating one example of an area A of FIG. 7 in detail.

FIG. 9 is an enlarged view of the light emitting element described with reference to FIG. 8.

FIG. 10 is a diagram to illustrate a contact path between a first electrode and a first contact electrode in the display panel illustrated with reference to FIG. 7.

FIG. 11 is a cross-sectional view illustrating another example of a cross-section of the display panel corresponding to the lines I1-I1′, I2-I2′, and I3-I3′ of FIG. 6.

FIG. 12 is a cross-sectional view illustrating one example of an area B in FIG. 11 in detail.

FIG. 13 is a cross-sectional view illustrating another example of a cross-section of a display panel corresponding to the lines I1-I1′, I2-I2′, and I3-I3′ of FIG. 6.

FIG. 14 is a cross-sectional view illustrating one example of area C of FIG. 13 in detail.

FIG. 15 is a cross-sectional view illustrating another example of a cross-section of a display panel corresponding to the lines I1-I1′, I2-I2′, and I3-I3′ of FIG. 6.

FIG. 16 is a cross-sectional view illustrating one example of an area D of FIG. 15.

FIG. 17 is a flowchart illustrating a method of manufacturing a display device according to one or more embodiments.

FIGS. 18-26 are cross-sectional views to illustrate a method of manufacturing a display device according to one or more embodiments.

FIG. 27 is a flowchart illustrating step S110 of FIG. 17 in detail.

FIGS. 28-34 are cross-sectional views to illustrate step S110.

FIG. 35 is an example diagram schematically showing a virtual reality device including a display device according to one or more embodiments;

FIG. 36 is an example diagram schematically showing a smart device including a display device according to one or more embodiments;

FIG. 37 is a diagram of an example schematically showing a vehicle including a display device according to one or more embodiments; and

FIG. 38 is a diagram of an example schematically showing a transparent display device including a display device according to one or more embodiments.

### DETAILED DESCRIPTION

The embodiments will now be described more fully hereinafter with reference to the accompanying drawings. The disclosed embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, and/or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, one or more embodiments of the present disclosure will be described in detail with reference to the accompanying drawings.

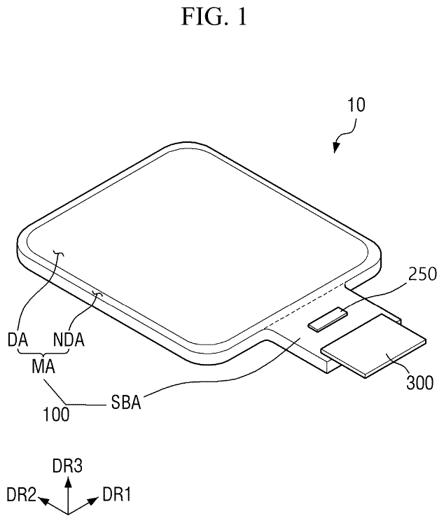

FIG. 1 is a perspective view illustrating a display device according to one or more embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and/or ultra mobile PCs (UMPC), as well as display screens for a variety of products such as televisions, laptops, monitors, billboards, and/or the internet of things (IoT).

The display device 10 may be a light emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but the present disclosure is not limited thereto. On the other hand, a micro light emitting diode referred to as a light emitting element in the following for convenience of explanation.

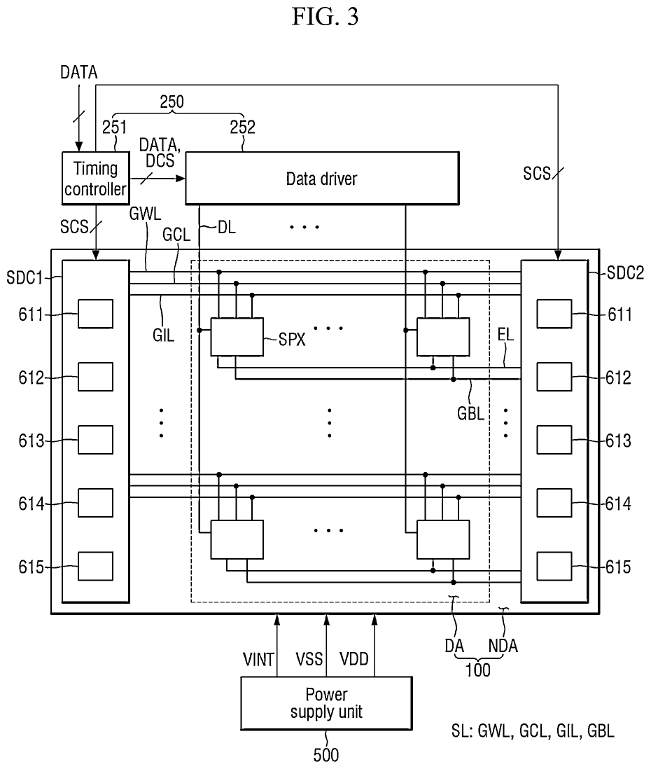

The display device 10 includes a display panel 100, a display driving circuit 250, a circuit board 300, and a power supply circuit 500 (e.g., see FIG. 3).

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a desired curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be formed to be flexible, such as to be able to be bent, curved, bent, folded, and/or rolled.

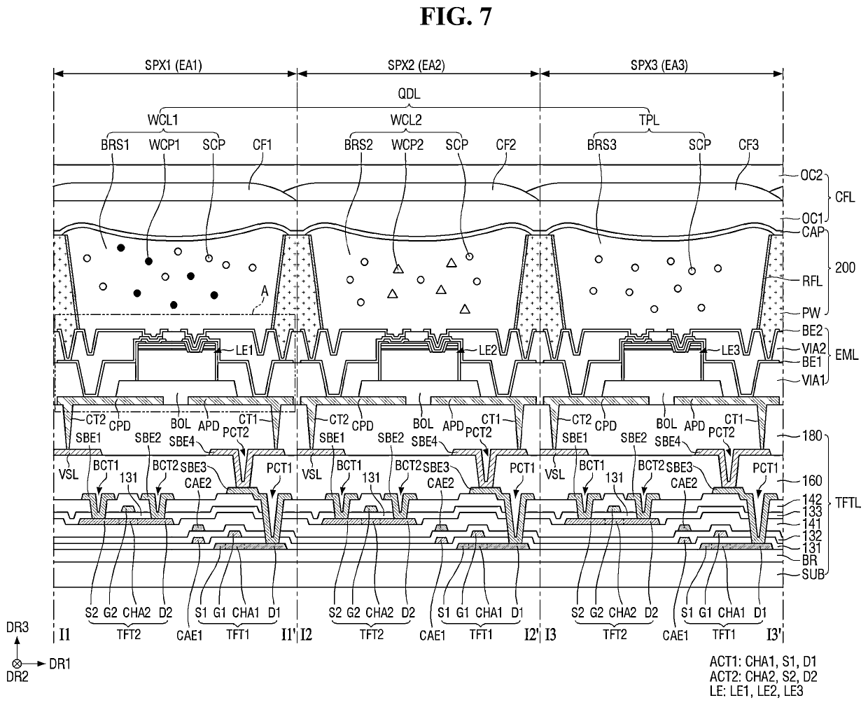

The substrate SUB (e.g., FIG. 7) of the display panel 100 may include a main area MA and a sub-area SBA.

The main area MA may include a display area DA that displays an image and a non-display area NDA that is a peripheral area of the display area DA and is around (e.g., surrounds) the display area along an edge or a periphery of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be disposed on the bottom surface of the display panel 100. When the sub-area SBA is bent, it may overlap the main area MA in the third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the indication panel 100 using a chip on glass (COG) method, a chip on plastic (COP) method, or an ultrasonic bonding method but is not limited thereto. For example, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and/or driving voltages through the circuit board 300. The circuit board 300 may be a flexible film, such as a flexible printed circuit board (FPCB), a printed circuit board (PCB), or a chip on film.

The power supply circuit 500 (e.g., FIG. 3) may generate a plurality of panel driving voltages according to an external power supply voltage. The power supply circuit 500 may be formed as an integrated circuit (IC) and attached to the circuit board 300 using a COF method.

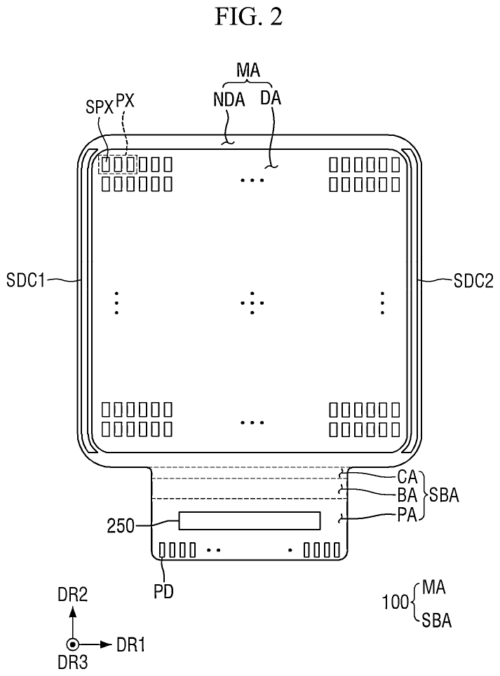

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driving unit SDC1 and a second scan driving unit SDC2 may be disposed in the non-display area NDA. The first scan driving unit SDC1 is disposed on one side (for example, the left side) of the display panel 100, and the second scan driving unit SDC2 is disposed on the other side (for example, the right side) of the display panel 100. However, it is not limited to. Each of the first scan driving unit SDC1 and the second scan driving unit SDC2 may be electrically connected to the display driving circuit 250 through scan fan-out lines. Each of the first scan driving unit SDC1 and the second scan driving unit SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub-area SBA is smaller than the length in the first direction DR1 of the main area MA or may be substantially equal to the length in the first direction DR1 of the main area MA. The sub-area SBA may be curved and may be disposed at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads PD of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

FIG. 3 is a block diagram illustrating a display device according to one or more embodiments.

Referring to FIG. 3, the display area DA includes a plurality of pixels PX, a plurality of scan lines SL (e.g., GWL, GCL, GIL, GBL), a plurality of emission control lines EL, and a plurality of data lines DL.

The plurality of pixels PX may be arranged in a matrix form along the first direction DR1 and the second direction DR2. The plurality of scan lines SL and the plurality of emission control lines EL may extend in the first direction DR1 and may be arranged along the second direction DR2. The plurality of data lines DL may extend in the second direction DR2 and may be arranged along the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light via light emitting elements according to the data voltage.

The non-display area NDA includes a first scan driving unit SDC1, a second scan driving unit SDC2, and a display driving circuit 250.

Each of the first scan driving unit SDC1 and the second scan driving unit SDC2 may include a write scan signal output unit 611, a control scan signal output unit 612, an initialization scan signal output unit 613, a bias scan signal output unit 614, and a light emitting signal output unit 615. Each of the write scan signal output unit 611, the control scan signal output unit 612, the initialization scan signal output unit 613, the bias scan signal output unit 614, and the light emitting signal output unit 615 may receive a scan timing control signal SCS from the timing control circuit 400. The write scan signal output unit 611 may generate write scan signals according to the scan timing control signal SCS of the timing control circuit 251 and sequentially output them to the write scan lines GWL. The control scan signal output unit 612 may generate control scan signals according to the scan timing control signal SCS and sequentially output them to the control scan lines GCL. The initialization scan signal output unit 613 may generate initialization scan signals according to the scan timing control signal SCS and sequentially output them to the initialization scan lines GIL. The bias scan signal output unit 614 may generate bias scan signals according to the scan timing control signal SCS and sequentially output them to the bias scan lines GBL. The light emitting signal output unit 615 may generate light emitting control signals according to the scan timing control signal SCS and sequentially output them to the emission control lines EL.

The display driving circuit 250 includes a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data and timing signals from an external source. The timing control circuit 251 may generate the scan timing control signal SCS and the data timing control signal DCS to control the display panel 100 according to timing signals. The timing control circuit 400 may output the scan timing control signal SCS to the first scan driving unit SDC1 and the second scan driving unit SDC2. The timing control circuit 251 may output digital video data DATA and a data timing control signal DCS to the data driving circuit 252.

The power supply circuit 500 may generate a plurality of panel driving voltages according to an external power supply voltage. For example, the power supply circuit 500 may generate and supply a first driving voltage VDD, a second driving voltage VSS, and a third driving voltage VINT to the display panel 100.

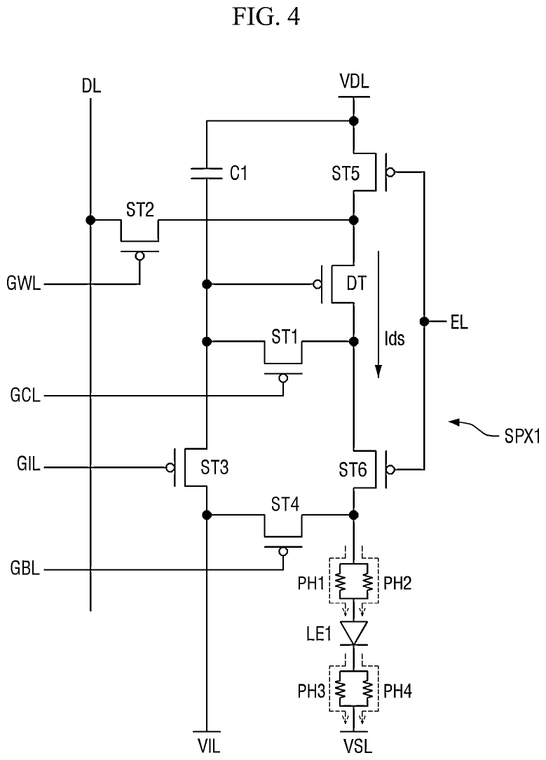

FIG. 4 is a circuit diagram illustrating a first sub-pixel of a display panel according to one or more embodiments.

Referring to FIG. 4, the first sub-pixel SPX1 according to one or more embodiments may be connected to scan lines GWL, GIL, GCL, and GBL, an emission line EL, and a data line DL. For example, the first sub-pixel SPX1 may be connected to the write scan line GWL, the initialization scan line GIL, the control scan line GCL, the bias scan line GBL, the emission line EL, and the data line DL.

The first sub-pixel SPX1 according to one embodiment includes a driving transistor DT, switch elements, a capacitor C1, and a first light emitting element LE1. The switch elements include first to sixth transistors ST1, ST2, ST3, ST4, ST5, and ST6.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode.

The first light emitting element LE1 may be a micro light-emitting diode.

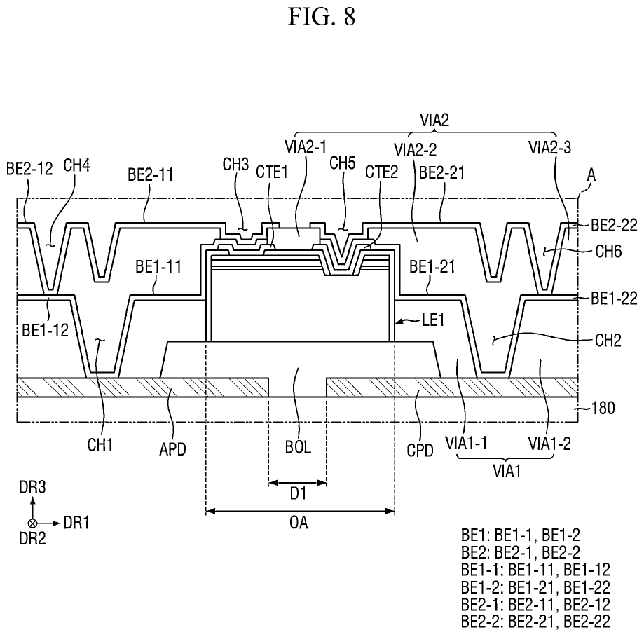

The first light emitting element LE1 emits light according to the driving current Ids. The amount of light emitted from the first light-emitting element LE1 may be proportional to the driving current Ids. An anode electrode of the first light emitting element LE1 may be connected in parallel to the first electrode of the fourth transistor ST4 and the second electrode of the sixth transistor ST6 through a first path PH1 and a second path PH2, and a cathode electrode may be connected in parallel to a second power supply line VSL to which the second power voltage is applied through a third path PH3 and a fourth path PH4. The parallel connection of the anode electrode and the cathode electrode will be described with reference to FIGS. 8-10. The first contact electrode CTE1 of the first light emitting element LE1 shown in FIGS. 8-10 is an anode electrode, and the second contact electrode CTE2 of the second light emitting element LE2 is a cathode electrode.

The capacitor C1 Is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. The gate electrodes of the fifth and sixth transistors ST5 and ST6 may be connected to the emission line EL. Because the first to sixth transistors ST1, ST2, ST3, ST4, ST5, and ST6 are formed as p-type MOSFET, they may be turned on when a scan signal of the gate low voltage and an emission signal are applied to the control scan line GCL, the initialization scan line GIL, the write scan line GWL, the bias scan line GBL, and the emission line EL, respectively. One electrode of the third transistor ST3 and one electrode of the fourth transistor ST4 may be connected to an initialization voltage line VIL.

The first electrode of the first transistor ST1 may be connected to the second electrode of the driving transistor DT and the second electrode of the first transistor ST1 may be connected to the gate electrode of the driving transistor DT. As such, when the first transistor ST1 is turned on, the driving transistor may be diode-connected. The first electrode of the second transistor ST2 may be connected to a data line DL and the second electrode of the second transistor ST2 may be connected to the first electrode of the driving transistor DT. The first electrode of the third transistor ST3 may be connected to the gate electrode of the driving transistor DT and the second electrode of the third transistor ST3 may be connected to the initialization voltage line VIL. The first electrode of the fourth transistor ST4 may be connected to the second electrode of the sixth transistor ST6 and the second electrode of the fourth transistor ST4 may be connected to the initialization voltage line VIL. The first electrode of the fifth transistor ST5 may be connected to the first power supply line VDL and the second electrode of the fifth transistor ST5 may be connected to the first electrode of the driving transistor DT. The first electrode of the sixth transistor ST6 may be connected to the second electrode of the driving transistor DT and the second electrode of the sixth transistor ST6 may be connected to the first electrode of the first light emitting element LE1.

In addition, the first light emitting element LE1 may be connected in parallel to each of the anode electrode and the cathode electrode to improve reliability.

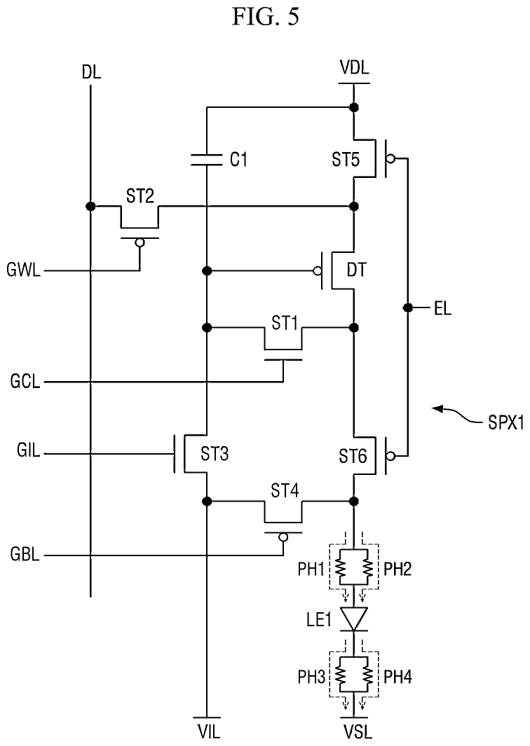

FIG. 5 is a circuit diagram illustrating a first sub-pixel of a display panel, according to one or more embodiments.

Referring to FIG. 5, the driving transistor DT, the second transistor ST2, the fourth transistor ST4, the fifth transistor ST5, and the sixth transistor ST6 are formed of p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Because the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as p-type MOSFET, so they may be turned on when a scan signal with a gate low voltage and an emission signal are applied to the write scan line GWL, the bias scan line GBL, and the emission line EL, respectively.

Alternatively, the fourth transistor ST4 in FIG. 5 may be formed of the n-type MOSFET. In this case, the active layer of each fourth transistor ST4 may be formed of the oxide semiconductor. When the fourth transistor ST4 is formed of n-type MOSFET, it may be turned on when a bias scan signal of a gate high voltage is applied to the bias scan line GBL.

Alternatively, although not shown in FIGS. 4 and 5, the first to sixth transistors ST1, ST2, ST3, ST4, ST5, and ST6 and the driving transistor DT may all be formed as n-type MOSFET.

In one or more embodiments, the circuit diagram of the second sub-pixel and the third sub-pixel according to one or more embodiments are substantially the same as the circuit diagram of the first sub-pixel SPX1 described in conjunction with FIGS. 4 and 5, so a description thereof will be omitted.

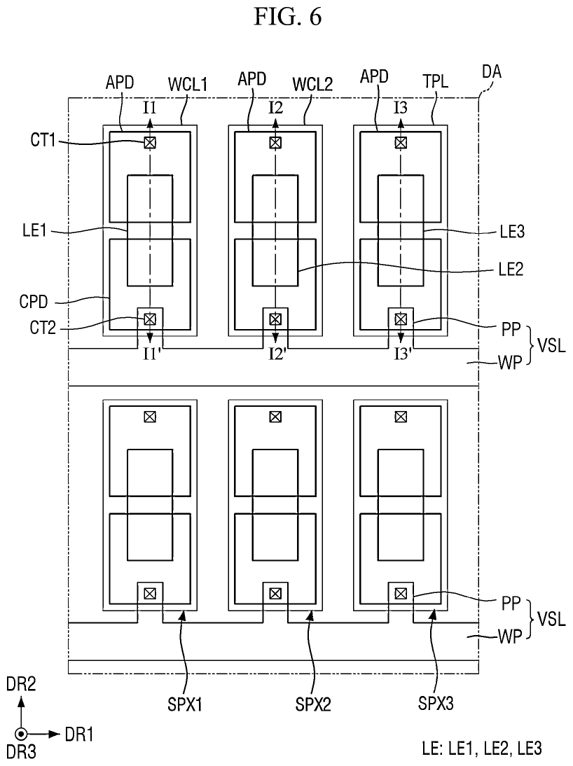

FIG. 6 is a layout diagram illustrating pixels of a display area according to one or more embodiments.

Referring to FIG. 6, each of the plurality of pixels PX in the display area DA may include a first sub-pixel SPX1, a second sub-pixel SPX2, and a third sub-pixel SPX3.

The plurality of pixels PX may be arranged in a matrix form. In each of the plurality of pixels PX, the first sub-pixel SPX1, the second sub-pixel SPX2, and the third sub-pixel SPX3 may be arranged along the first direction DR1.

The first sub-pixel SPX1 may emit light of a first color, the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may indicate that the main peak wavelength of the light is included in a wavelength band from approximately 370 μm to 460 μm, the green wavelength band may indicate that the main peak wavelength of the light is included in a wavelength band from approximately 480 μm to 560 μm, and the red wavelength band may indicate that the main peak wavelength of the light is included in a wavelength band from approximately 600 μm to 750 μm.

The first sub-pixel SPX1 includes a first electrode APD, a first light emitting element LE1, a second electrode CPD, a first connection hole CT1, a second connection hole CT2, and a first light conversion layer WCL1. The second sub-pixel SPX2 includes the first electrode APD, a second light emitting element LE2, the second electrode CPD, the first connection hole CT1, the second connection hole CT2, and a second light conversion layer WCL2. The third sub-pixel SPX3 includes the first electrode APD, a third light emitting element LE3, the second electrode CPD, the first connection hole CT1, the second connection hole CT2, and a light transmitting layer TPL.

The first electrode APD and the second electrode CPD may be arranged to be spaced from each other. Each of the first electrode APD and the second electrode CPD may have a rectangular planar shape. The first electrode APD and the second electrode CPD may have substantially the same area, but the present disclosure is not limited thereto.

In one or more embodiments, the area of the first sub-pixel SPX1, the area of the second sub-pixel SPX2, and the area of the third sub-pixel SPX3 are exemplified as being equal but are not limited thereto. For example, the area of the first sub-pixel SPX1, the area of the second sub-pixel SPX2, and the area of the third sub-pixel SPX3 may be set differently depending on the light conversion efficiency of the first light conversion layer WCL1 and the light conversion efficiency of the second light conversion layer WCL2.

The area of the first electrode APD may be the same as the area of the second electrode CPD, but the present disclosure is not limited thereto.

The first electrode APD may be electrically connected to the second electrode of the fourth transistor (ST4 in FIGS. 4 and 5) and the second electrode of the sixth transistor (ST6 in FIGS. 4 and 5) of the corresponding sub-pixel SPX1, SPX2, and SPX3 through the first connection hole CT1.

The second electrode CPD may be connected to the second power supply line VSL to which the second driving voltage VSS is applied through the second connection hole CT2. Therefore, the second driving voltage VSS may be applied to the second electrode CPD.

The plurality of light emitting elements LE may emit the third light, that is, light in the blue wavelength band.

The first light conversion layer WCL1 may completely overlap the first light emitting element LE1 of the first sub-pixel SPX1. The area of the first light conversion layer WCL1 is larger than the area of the first light emitting element LE1. The first light conversion layer WCL1 may convert or shift the peak wavelength of incident light into light of another specific peak wavelength and emit the light. For example, the first light conversion layer WCL1 may convert or shift the third light emitted from the plurality of light emitting elements LE of the first sub-pixel SPX1 into first light.

The second light conversion layer WCL2 may completely overlap the second light emitting element LE2 of the second sub-pixel SPX2. The area of the second light conversion layer WCL2 may be larger than the area of the second light emitting element LE2. The second light conversion layer WCL2 may convert or shift the peak wavelength of incident light into light of another specific peak wavelength and emit the light. For example, the second light conversion layer WCL2 may convert or shift the third light emitted from the second light emitting elements LE2 of the second sub-pixel SPX2 into second light.

The light transmitting layer TPL may completely overlap the third light emitting element LE3 of the third sub-pixel SPX3. The light transmitting layer TPL may transmit incident light as it is. For example, the light transmitting layer TPL may transmit the third light emitted from the third light emitting element LE3 of the third sub-pixel SPX3 as it is.

The first connection hole CT1 may be an area where the first electrode APD is connected to the fourth source connection electrode SBE2 in FIG. 7, which is electrically connected to a first source area S1 or a first drain area D1 of the first thin film transistor (TFT1 in FIG. 7). The first connection hole CT1 may overlap the first electrode APD.

The second connection hole CT2 may be an area where the second electrode CPD is connected to the second power supply line VSL. The second connection hole CT2 may overlap the second electrode CPD and the second power supply line VSL.

Each of the second power supply lines VSL may be electrically connected to a non-visible power supply line disposed in the non-display area NDA as shown in FIG. 2. Each of the second power supply lines VSL may include a wire portion WP extending in the first direction DR1 and a protrusion portion PP projecting from the wire portion WP in the second direction DR2 and overlapping the second connection hole CT2.

However, the present disclosure is not limited thereto, and each of the plurality of pixels PX may include four sub-pixels, including a first sub-pixel, a second sub-pixel, a third sub-pixel, and a fourth sub-pixel, and the second sub-pixel and the fourth sub-pixel may emit light of the same color. For example, the first sub-pixel may emit first red light, the second sub-pixel may emit second green light, the third sub-pixel may emit blue light, and the fourth sub-pixel may emit green light. If the pixel PX includes four sub-pixels, the first sub-pixel and the second sub-pixel may be arranged along the first direction DR1, and the first sub-pixel and the third sub-pixel may be arranged along the second direction DR2, and the second sub-pixel and the fourth sub-pixel may be arranged along the second direction DR2.

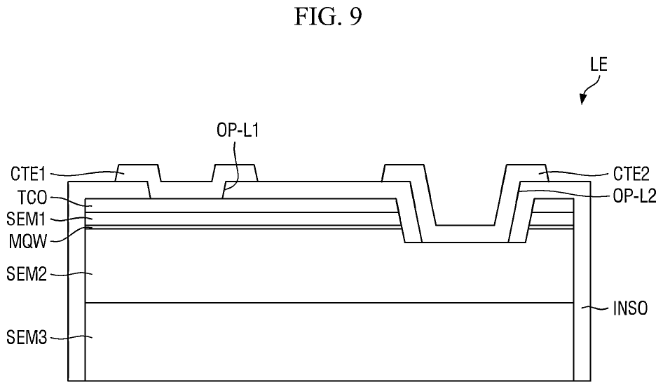

FIG. 7 is a cross-sectional view illustrating one example of a cross-section of the display panel corresponding to the lines I1-I1′, I2-I2′, and I3-I3′ of FIG. 6. FIG. 8 is a cross-sectional view illustrating one example of an area A of FIG. 7 in detail. FIG. 9 is an enlarged view of the light emitting element LE described with reference to FIG. 8.

Referring to FIGS. 7 and 8, a substrate SUB may be made of an insulating material such as glass, polymer resin, and/or the like. If the substrate SUB is made of polymer resin, it may be a flexible substrate that may be stretched. The polymer resin may be acryl resin, epoxy resin, phenolic resin, polyamide resin, and/or polyimide resin.

A barrier film BR may be disposed on the substrate SUB. The barrier film BR is a membrane for protecting the transistors of a thin film transistor layer TFTL and a light emitting element layer EML from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminum oxide layer.

A first thin film transistor TFT1 may be disposed on the barrier film BR. The first thin film transistor TFT1 may be either the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be disposed on the barrier film BR. The first active layer ACT1 of the first thin film transistor TFT1 may include polycrystalline silicon, single crystalline silicon, low-temperature polycrystalline silicon, and/or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate insulating layer 131 may be disposed on the first channel area CHA1, the first source area S1, and the first drain area D1 of the first thin film transistor TFT1 and the barrier film BR. The first gate insulating layer 131 may be formed of an inorganic film, for example, a silicon nitride layer, a silicon oxynitride layer, a silicon oxide layer, a titanium oxide layer, and/or an aluminum oxide layer.

A first gate metal layer may be disposed on the first gate insulating film 131. The first gate metal layer may include the first gate electrode G1 of the first thin film transistor TFT1 and a first capacitor electrode CAE1. The first gate electrode G1 may overlap the first active layer ACT1 in the third direction DR3. In FIG. 7, the first gate electrode G1 and the first capacitor electrode CAE1 are shown to be spaced from each other, but the first gate electrode G1 and the first capacitor electrode CAE1 may be connected to each other. The first gate metal layer may be formed as a single layer or multiple layers of one of molybdenum (Mo), aluminum (AI), chromium (Cr), gold (Au), titanium (Ti), nickel (Ni), neodymium (Nd), and/or copper (Cu), and/or an alloy thereof.

A second gate Insulating film 132 may be disposed on the first gate electrode G1 of the first thin film transistor TFT1, the first capacitor electrode CAE1, and the first gate insulating film 131. The second gate insulating layer 132 may be formed of an inorganic film, for example, a silicon nitride layer, a silicon oxynitride layer, a silicon oxide layer, a titanium oxide layer, and/or an aluminum oxide layer.

A second gate metal layer may be disposed on the second gate insulating film 132. The second gate metal layer may include a second capacitor electrode CAE2. The second capacitor electrode CAE2 may overlap the first capacitor electrode CAE1 in the third direction DR3. Because the second gate insulating film 132 has a suitable permittivity (e.g., a predetermined permittivity), a capacitor (C1 in FIG. 5) may be formed by the first capacitor electrode CAE1, the second capacitor electrode CAE2, and the second gate insulating film 132 disposed between them. The second gate metal layer may be formed as a single layer or multiple layers of one of molybdenum (Mo), aluminum (AI), chromium (Cr), gold (Au), titanium (Ti), nickel (Ni), neodymium (Nd), and/or copper (Cu), and/or an alloy thereof.

A first Interlayer Insulating film 141 may be disposed on the second capacitor electrode CAE2 and the second gate insulating layer 132. The first interlayer insulating layer 141 may be formed of an inorganic film, such as a silicon nitride layer, a silicon oxynitride layer, a silicon oxide layer, a titanium oxide layer, and/or an aluminum oxide layer.

A second thin film transistor TFT2 may be disposed on the first interlayer insulating film 141. The second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be disposed on the first interlayer insulating film 141. The second active layer ACT2 may include an oxide semiconductor. For example, the second active layer ACT2 may include IGZO (indium (In), gallium (Ga), zinc (Zn) and oxygen (O)), and/or IGZTO (indium (In), gallium (Ga), zinc (Zn), tin (Sn) and oxygen (O)), or IGTO (indium (In), gallium (Ga), tin (Sn) and oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be disposed on one side of the second channel area CHA2, and the second drain area D2 may be disposed on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate insulating layer 133 may be disposed on the second active layer ACT2 of the second thin film transistor TFT2 and the first interlayer insulating film 141. The third gate insulating layer 133 may be formed of an inorganic film, for example, a silicon nitride layer, a silicon oxynitride layer, a silicon oxide layer, a titanium oxide layer, and/or an aluminum oxide layer.

A third gate metal layer may be disposed on the third gate insulating film 133. The third gate metal layer may include the second gate electrode G2 of the second thin film transistor TFT2. The second gate electrode G2 may overlap the second active layer ACT2 in the third direction DR3. The third gate metal layer may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

A second interlayer insulating film 142 may be disposed on the second gate electrode G2 of the second thin film transistor TFT2 and the third gate insulating film 133. The second interlayer insulating layer 142 may be formed of an inorganic film, for example, a silicon nitride layer, a silicon oxynitride layer, a silicon oxide layer, a titanium oxide layer, and/or an aluminum oxide layer.

A first data metal layer may be disposed on the second Interlayer Insulating film 142. The first data metal layer may include a first source connection electrode SBE3, a second source connection electrode SBE1, and a third source connection electrode SBE2. The first source connection electrode SBE3 may be connected to the first drain area D1 of the first active layer ACT1 through a first source contact hole PCT1 penetrating a first gate insulating film 131, a second gate insulating film 132, a first interlayer insulating film 141, a third gate insulating film 133, and a second interlayer insulating film 142. The second source connection electrode SBE1 may be connected to the second source area S2 of the second active layer ACT2 through a second source connection contact hole BCT1 penetrating the second interlayer insulating film 142 and the third gate insulating film 133. The third source connection electrode SBE2 may be connected to the second drain area D2 of the second active layer ACT2 through a third source connection contact hole BCT2 penetrating the second interlayer insulating film 142 and the third gate insulating film 133. The first data metal layer may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof. For example, the first data metal layer may include a first layer made of titanium (Ti), a second layer made of aluminum (Al), and/or a third layer made of titanium (Ti).

A first organic film 160 may be disposed to flatten the step due to the first thin film transistor TFT1 and the second thin film transistor TFT2 on the first source connection electrode SBE3, the second source connection electrode SBE1, and the third source connection electrode SBE2, and the second interlayer insulating film 142. The first organic film 160 may be formed from an organic film such as acrylic resin, epoxy resin, phenolic resin, polyamide resin, polyimide resin, and/or the like.

A second data metal layer may be disposed on the first organic film 160. The second data metal layer may include a fourth source connection electrode SBE4 and the second power supply line VSL. The fourth source connection electrode SBE4 may be connected to the first source connection electrode SBE3 through a second pixel contact hole PCT2 penetrating the first organic film 160. The second data metal layer may be formed as a single layer or multiple layers of one of molybdenum (Mo), aluminum (AI), chromium (Cr), gold (Au), titanium (Ti), nickel (Ni), neodymium (Nd), and/or copper (Cu), and/or an alloy thereof. For example, the second data metal layer may include a first layer made of titanium (Ti), a second layer made of aluminum (AI), and/or a third layer made of titanium (Ti).

A second organic layer 180 may be disposed on the fourth source connection electrode SBE4, the second power supply line VSL, and the first organic film 160. The second organic layer 180 may be formed of an organic film such as acrylic resin, epoxy resin, phenolic resin, polyamide resin, polyimide resin, and/or the like.

The light emitting element layer EML may be disposed on the second organic layer 180. The light emitting element layer EML may include a first electrode APD, a second electrode CPD, an organic pattern layer BOL, light emitting elements LE1, LE2, and LE3, a first via layer VIA1, a second via layer VIA2, a lower connection electrode BE1, and an upper connection electrode BE2.

The first electrode APD and the second electrode CPD may be disposed on the second organic layer 180 to be spaced from each other. Each sub-pixel SPX1, SPX2, and SPX3 may include a pair of first electrodes APD and second electrodes CPD. The first electrode APD of each sub-pixel SPX1, SPX2, and SPX3 may be connected to a fourth source connecting electrode SBE4 through a respective connection hole (CT1 in FIG. 6) penetrating the second organic layer 180.

In the first through third sub-pixels SPX1, SPX2, SPX3, the first electrode APD may be connected to the first source electrode S1 or the second drain electrode D1 of the first thin film transistor TFT1 through the first source connection electrode SBE3 and the fourth source connection electrode SBE4. Therefore, a voltage controlled by the first thin film transistor TFT1 in each sub-pixel SPX1, SPX2, and SPX3 may be applied to the first electrode APD. The first electrode APD may be an anode electrode.

The second electrode CPD may be connected to the second power supply line VSL through a second connection hole (CT2 in FIG. 6) penetrating the second organic layer 180. Therefore, the second driving voltage VSS may be applied to the second electrode CPD. The second electrode CPD may be a cathode electrode.

The first electrode APD and the second electrode CPD may be formed as a single layer or multiple layers of one of molybdenum (Mo), aluminum (Al), chromium (Cr), gold (Au), titanium (Ti), nickel (Ni), neodymium (Nd), and copper (Cu), and/or an alloy thereof. In one or more embodiments, the first electrode APD and the second electrode CPD may have a two-layer structure of titanium (Ti)/aluminum (AI) or titanium (Ti)/copper (Cu), and/or a three-layer structure of titanium (Ti)/aluminum (Al)/titanium (Ti) and/or titanium (Ti)/copper (Cu).

The first electrode APD and the second electrode CPD may be spaced from each other on a same plane and may be arranged to protrude outward from the light emitting element LE. The first electrode APD and the second electrode CPD may be spaced from each other by a first separation distance D1. The first separation distance D1 may be less than the width of the light emitting element LE. The first separation distance D1 may be from about 4 μm to 6 μm.

The organic pattern layer BOL is disposed between the first electrode APD and the second electrode CPD and may cover the edges of the first electrode APD and the second electrode CPD. The organic pattern layer BOL serves to temporarily fix or adhere the plurality of light emitting elements LE to prevent the plurality of light emitting elements LE from tipping or falling over in the process of transferring the light emitting elements LE to the display panel 100. That is, the organic pattern layer BOL may be a layer for temporarily adhering the light emitting element LE to the first electrode APD and the second electrode CPD. To facilitate temporary adhesion, the thickness of the organic pattern layer BOL may be greater than the thickness of each of the first electrode APD and the second electrode CPD but is not limited thereto. After the transfer process of the light emitting element LE is completed, the organic pattern layer BOL may be cured or the like to create a robust defect between the light emitting element LE and the organic pattern layer BOL. Unlike the conventional (Eutectic) bonding process, the bonding process using the organic pattern layer BOL does not require heat and pressure to damage the light emitting element LE, so it has the effect of preventing defects in the light emitting element LE.

The organic pattern layer BOL may be an Insulating material without electrical connection. Further, the organic pattern layer BOL may be a photosensitive organic film such as photoresist. Alternatively, the organic pattern layer BOL may be formed of acrylic resin, epoxy resin, phenolic resin, polyamide resin, polyimide resin, and/or the like.

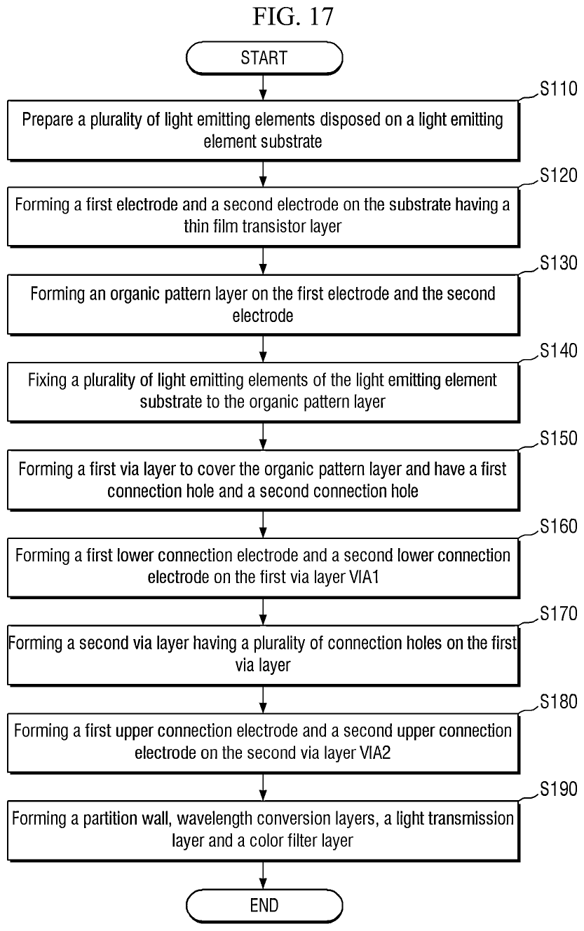

A detailed description of the organic pattern layer BOL will be described later in the manufacturing method of the display device 10 referring to FIGS. 17-25.

The light emitting elements LE may be disposed on the organic pattern layer BOL in an opening OA of the first via layer VIA1. The light emitting element LE may be flip-type micro-LED. The flip-type micro-LED refers to an LED in which contact electrodes CTE1 and CTE2 are formed on one surface (e.g., top surface) of the light emitting element LE (e.g., LE:LE1, LE2, LE3).

Each of the plurality of light emitting elements LE may be formed of an inorganic material such as gallium nitride (GaN).

Each of the plurality of light emitting elements LE may be formed by growing on a semiconductor substrate such as a silicon substrate and/or sapphire substrate. The plurality of light emitting elements LE may be directly transferred from the semiconductor substrate onto the electrodes APD and CPD of the display panel 100. Alternatively, the plurality of light emitting elements LE may be transferred onto the electrodes APD and CPD of the display panel 100 by an electrostatic method using an electrostatic head or by a stamp method using an elastic polymeric material such as PDMS and/or silicone as a transfer substrate.

Referring to FIG. 9, the light emitting element LE may be a light emitting structure including a third semiconductor layer SEM3, a second semiconductor layer SEM2, an active layer MQW, a first semiconductor layer SEM1, a transparent conductive layer TCO, a first contact electrode CTE1, a second contact electrode CTE2, and an element insulating layer INS0. Referring to FIG. 9, a flip-type light emitting element LE in which the first contact electrode CTE1 and the second contact electrode CTE2 are disposed on one side of the light emitting element LE is illustrated, but it is not limited thereto, and a vertical light emitting element LE may also be adopted. The third semiconductor layer SEM3 may include an undoped semiconductor and may be a material that is not doped as n-type or p-type. In one or more embodiments, a third semiconductor material layer SEM3 may be at least one of undoped InAlGaN, GaN, AlGaN, InGaN, AlN, and/or InN, but is not limited thereto.

The second semiconductor layer SEM2 may be disposed on the third semiconductor layer SEM3. The second semiconductor layer SEM2 may be doped with a second conductive dopant such as Si, Ge, Sn, and/or the like. For example, the second semiconductor layer SEM2 may be n-GaN doped with n-type Si. The thickness of the second semiconductor layer SEM2 may be approximately 500 nm to 1 μm.

The active layer MQW may be disposed on the second semiconductor layer SEM2. The active layer MQW may emit light by combining electron-hole pairs according to electrical signals applied through the first semiconductor layer SEM1 and the second semiconductor layer SEM2. The active layer MQW may emit first light having a central wavelength range of 450 nm to 495 nm, that is, light in the blue wavelength band.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN and/or AlGaN but is not limited thereto. The thickness of the well layer may be approximately 1 to 4 nm, and the thickness of the barrier layer may be approximately 3 to 10 nm.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light. The light emitted from the active layer MQW is not limited to the first light (e.g., light in the blue wavelength band) and may emit second light (e.g., light in the green wavelength band) or third light (e.g., light in the red wavelength band) in some cases. The thickness of the active layer MQW may be approximately 10 nm to 25 nm.

The first semiconductor layer SEM1 may be doped with a first conductive dopant such as Mg, Zn, Ca, Se, and/or Ba. For example, the first semiconductor layer SEM1 may be p-GaN doped with p-type Mg. The thickness of the first semiconductor layer SEM1 may be approximately 30 nm to 200 nm.

In one or more embodiments, a superlattice layer may be further included between the active layer MQW and the second semiconductor layer SEM2. The superlattice layer may be a layer for relieving stress between the second semiconductor layer SEM2 and the active layer MQW. The superlattice layer may be formed of InGaN and/or GaN. In addition, an electron blocking layer may be further included between the first semiconductor layer SEM1 and the active layer MQW. The electron blocking layer may be a layer to suppress or prevent too many electrons from flowing into the active layer MQW. For example, the electron blocking layer may be p-AlGaN doped with p-type Mg. The thickness of the electron blocking layer may be approximately 10 to 50 nm. The electronic blocking layer may be omitted.

The transparent conductive layer TCO may be disposed on the first semiconductor layer SEM1. The transparent conductive layer TCO may be in direct contact with the first semiconductor layer SEM1. The transparent conductive layer TCO may be formed transparently to emit light. The transparent conductive layer TCO may be formed of a transparent conductive oxide such as indium tin oxide (ITO) and/or indium zinc oxide (IZO). The transparent conductive layer TCO may be omitted.

An element insulating layer INS0 may be formed to wrap the sides of the third semiconductor layer SEM3, the second semiconductor layer SEM2, the active layer MQW, the first semiconductor layer SEM1, and the transparent conductive oxide TCO and the top surface of the transparent conductive oxide TCO. The element insulating layer INS0 has two openings. For example, the element insulating layer INS0 includes a first opening OP-L1 and a second opening OP-L2. The element insulating layer INS0 may be formed of an inorganic film, for example, a silicon nitride layer, a silicon oxynitride layer, a silicon oxide layer, a titanium oxide layer, and/or an aluminum oxide layer.

The first contact electrode CTE1 and the second contact electrode CTE2 are disposed on the two openings. For example, the first contact electrode CTE1 may be disposed on the first opening OP-L1 and contact the first semiconductor layer SEM1 via the transparent conductive oxide TCO. The second contact electrode CTE2 may be disposed on the second opening OP-L2 and contact the second semiconductor layer SEM2. To this end, the second opening OP-L2 may expose the second semiconductor layer SEM2. The second opening OP-L2 may have a wider diameter than the first opening OP-L1.

The element insulating layer INS0 may be disposed to cover the side surfaces of the recess defined by the second opening OP-L2.

Because the first contact electrode CTE1 and the second contact electrode CTE2 are disposed on the top surface of the light emitting element LE, they may be transparent electrodes. For example, the first contact electrode CTE1 and the second contact electrode CTE2 may be formed of a transparent conductive oxide such as indium tin oxide (ITO) and/or indium zinc oxide (IZO). However, it is not limited thereto, and in one or more embodiments, the first contact electrode CTE1 and the second contact electrode CTE2 may be disposed on the lower surface of the light emitting element LE. When the first contact electrode CTE1 and the second contact electrode CTE2 are disposed on the lower surface of the light emitting element LE, the first contact electrode CTE1 and the second contact electrode CTE2 of the light emitting element LE may be formed as a single layer or multiple layers of a material selected from the group consisting of Ti, Cr, Al, Cu, and Au, as well as a transparent conductive oxide. In one or more embodiments, the first contact electrode CTE1 may be a vertical light emitting element LE disposed on the upper surface of the light emitting element LE, and the second contact electrode CTE2 may be a vertical light emitting element LE disposed on the lower surface of the light emitting element LE. When the vertical-type light emitting element LE is adopted the connection structure may be added or deleted to match the electrode structure depending on the structure of the light emitting element LE. Referring again to FIGS. 7 and 8, the first via layer VIA1 supports a lower connection electrode BE1 and flattens the step formed by the light emitting element LE.

The first via layer VIA1 may include a plurality of connection holes CH1 and CH2. For example, the first via layer VIA1 may include a first connection hole CH1 formed on the first electrode APD and a second connection hole CH2 formed on the second electrode CPD. The first connection hole CH1 exposes the first electrode APD of the light emitting element LE, and the second connection hole CH2 exposes the second electrode CPD of the light emitting element LE. The first via layer VIA1 may include a first flat portion VIA1-1 disposed between the light emitting element LE and the connection holes CH1 and CH2, and a second flat portion VIA1-2 disposed on a side farther from the light emitting element LE relative to the second connection hole CH2.

The lower connection electrode BE1 may include a first lower connection electrode BE1-1 and a second lower connection electrode BE1-2. The first lower connection electrode BE1-1 connects the first contact electrode CTE1 with the first electrode APD, and the second lower connection electrode BE1-2 connects the second contact electrode CTE2 with the second electrode CPD. The first lower connection electrode BE1-1 and the second lower connection electrode BE1-2 are spaced from each other at the top of the light emitting element LE.

The first lower connection electrode BE1-1 connects the first contact electrode CTE1 and the first electrode APD through the first connection hole CH1.

The first lower connection electrode BE1-1 may include a first lower connection portion BE1-11 and a second lower connection portion BE1-12. The first lower connection portion BE1-11 and the second lower connection portion BE1-12 are connected to each other. In one or more embodiments, the first lower connection portion BE1-11 and the second lower connection portion BE1-12 may be formed integrally with each other. The first lower connection portion BE1-11 may be disposed so that it is in contact with the first contact electrode CTE1 and extends to the first electrode APD exposed by the first connection hole CH1 along the side of the first light emitting element LE1 and the first flat portion VIA1-1. The second lower connection portion BE1-12 may be disposed extending from the second electrode APD exposed by the first connection hole CH1 to the second flat portion VIA1-2.

The second lower connection electrode BE1-2 connects the second contact electrode CTE2 and the second electrode CPD through the second connection hole CH2.

The second lower connection electrode BE1-2 may include a first lower connection portion BE1-21 and a second lower connection portion BE1-22. The first lower connection portion BE1-21 and the second lower connection portion BE1-22 are connected to each other. The first lower connection portion BE1-21 may be disposed extending from the second contact electrode CTE2 to the second electrode CPD exposed by the second connection hole CH2 along the first flat portion VIA1-1 along the side of the first light emitting element LE1. The second lower connection portion BE1-22 may be disposed extending along the second flat portion VIA1-2 from the second electrode CPD exposed by the second connection hole CH2. The first via layer VIA1 may be formed of an organic film such as acrylic resin, an epoxy resin, phenolic resin, polyamide resin, polyimide resin, and/or the like. The height of the first via layer VIA1 may be formed to be lower than that of the light emitting element LE. The height of the first via layer VIA1 may be less than the height of the active layer MQW.

The second via layer VIA2 is disposed on the first via layer VIA1. The second via layer VIA2 supports the upper connection electrode BE2 and flattens the step formed by the light emitting element LE.

The upper connection electrode BE2 may include a first upper connection electrode BE2-1 and a second upper connection electrode BE2-2. The first upper connection electrode BE2-1 connects the first contact electrode CTE1 to the second lower connection BE1-12, and the second upper connection electrode BE2-2 connects the second contact electrode CTE2 to the second lower connection BE1-22. The first upper connection electrode BE2-1 and the second upper connection electrode BE2-2 are spaced from each other at the top of the light emitting element LE.

The second via layer VIA2 may include a plurality of connection holes CH3, CH4, CH5, and CH6. For example, the second via layer VIA2 may include a third connection hole CH3 and a fifth connection hole CH5 formed on the first light emitting element LE1, a fourth connection hole CH4 formed on the second lower connection BE1-12, and a sixth connection hole CH6 formed on the second lower connection BE1-22. The third connection hole CH3 exposes the first lower connection electrode BE1-1 in contact with the first contact electrode CTE1. The fourth connection hole CH4 exposes the second lower connection portion BE1-12 connected to the first electrode APD. The fifth connection hole CH5 exposes the second lower connection electrode BE1-2 in contact with the second contact electrode CTE2.

The second via layer VIA2 may be formed to cover the first light emitting element LE1. The second via layer VIA2 may be disposed higher than the light emitting element LE. The second via layer VIA2 may include a first planarization portion VIA2-1, a second planarization portion VIA2-2, and a third planarization portion VIA2-3. The first planarization portion VIA2-1 may be disposed between the third connection hole CH3 and the fifth connection hole CH5 disposed on the first light emitting element LE1. The third planarization portion VIA2-3 may be disposed outside the fourth connection hole CH4 and the sixth connection hole CH6. The second planarization portion VIA2-2 may be disposed between the first planarization portion VIA2-1 and the third planarization portion VIA2-3. That is, the third planarization portion VIA2-3 may be disposed further outside the first light emitting element LE1 than the second planarization portion VIA2-2.

The first upper connection electrode BE2-1 connects the first contact electrode CTE1 and the first electrode APD through the third connection hole CH3 and the fourth connection hole CH4. In one or more embodiments, the first upper connection electrode BE2-1 electrically connects the first contact electrode CTE1 and the first electrode APD through the third connection hole CH3 and the fourth connection hole CH4. Here, ‘electrically connected’ means that another connection layer may be added in the middle.

The first upper connection electrode BE2-1 may include a first upper connection portion BE2-11 and a second upper connection portion BE2-12. The first upper connection portion BE2-11 and the second upper connection portion BE2-12 are connected to each other. In one or more embodiments, the first upper connection portion BE2-11 and the second upper connection portion BE2-12 may be formed integrally with each other.

The first upper connection portion BE2-11 may be disposed extending from the first lower connection portion BE1-11 exposed through the third connection hole CH3 to the first lower connection portion BE1-12 exposed through the fourth connection hole CH4 along the second planarization portion VIA2-2. The second upper connection portion BE2-12 may be disposed extending along the third planarization portion VIA2-3 from the first lower connection portion BE1-12 exposed by the fourth connection hole CH4.

The second upper connection electrode BE2-2 connects the second contact electrode CTE2 and the second electrode CPD through the fifth connection hole CH5 and the sixth connection hole CH6.

The second upper connection electrode BE2-2 may include a first upper connection portion BE2-21 and a second upper connection portion BE2-22. The first upper connection portion BE2-21 and the second upper connection portion BE2-22 are connected to each other. The first upper connection portion BE2-21 may be disposed extending from the first lower connection portion BE1-21 exposed through the fifth connection hole CH5 to the second lower connection portion BE1-22 exposed through the sixth connection hole CH6 along the second planarization portion VIA2-2. The second upper connection portion BE2-22 may be disposed extending along the third planarization portion VIA2-3 from the second lower connection portion BE1-22 exposed by the sixth connection hole CH6.

The lower connection electrode BE1 and the upper connection electrode BE2 may include a transparent conductive material (TCO) such as indium tin oxide (ITO) and/or indium zinc oxide (IZO) that is capable of transmitting light. The second via layer VIA2 may be formed of the same material as the first via layer VIA1. The second via layer VIA2 may be formed from an organic film such as acrylic resin, epoxy resin, phenolic resin, polyamide resin, polyimide resin, and/or the like. The height of the first via layer VIA1 may be less than that of the light emitting element LE. The height of the first via layer VIA1 may be lower than the height of the active layer MQW.

A wavelength control portion 200 may be disposed on the light emitting element layer EML.

The wavelength control portion 200 may include a partition wall PW, a second reflective layer RFL, and a wavelength conversion layer QDL.

The partition wall PW is arranged to extend in the first direction DR1 and the second direction DR2 and may be formed in a grid-like pattern throughout the display area DPA. Furthermore, the partition PW may not overlap with the plurality of light emitting areas EA1, EA2, and EA3 and may overlap with the non-emitting area NEA.

The partition wall PW may serve to provide space for the wavelength conversion layer QDL to be formed. The partition wall PW may have a large thickness to provide a space for the wavelength conversion layer QDL to be formed. For example, the partition wall PW may include an organic insulating material so that the partition wall PW may be made thick. The organic insulating material may include, for example, epoxy-based resin, acrylic-based resin, cardo-based resin, and/or imide-based resin.

In one or more embodiments, the partition wall PW may include a first partition wall and a second partition wall that are sequentially stacked. In this case, the length of the first partition wall in the first direction DR1 or the second direction DR2 may be wider than the length of the second partition wall in the first direction DR1 or the second direction DR2. In one or more embodiments, the partition wall PW may block the transmission of light in the non-emitting area NEA. The partition wall PW may further include a light blocking material and may include a dye or pigment having light blocking properties. For example, the partition wall PW may include an inorganic black pigment such as carbon black or an organic black pigment. External light incident on the display device 10 from the outside may cause a problem that distorts the color gamut of the wavelength control portion 200. According to this embodiment, the partition wall PW including a light-blocking material is disposed in the wavelength control portion 200 so that at least a portion of external light is absorbed by the light-blocking material. Therefore, color distortion caused by external light reflection may be reduced. Furthermore, the partition wall PW including a light-blocking material may light from intruding between adjacent light emitting areas and causing mixing, thereby further improving the color reproduction rate.

The second reflective layer RFL may be disposed between the partition wall PW and the first light conversion layer WCL1, between the partition wall PW and the second light conversion layer WCL2, and between the partition wall PW and the light transmitting layer TPL. The second reflective layer RFL serves to reflect light traveling in the lateral direction from the first light conversion layer WCL1, the second light conversion layer WCL2, and the light transmitting layer TPL.

The second reflective layer RFL may include a highly reflective metal material such as aluminum (AI). The thickness of the second reflective layer RFL may be approximately 0.1 μm.

Alternatively, the second reflective layer RFL may include M (where M is an integer greater than or equal to 2) pairs of first and second layers having different refractive indices to act as Distributed Bragg Reflectors (DBR). In this case, M first layers and M second layers may be arranged alternately. The first layer and the second layer may be formed of an inorganic film, for example, a silicon nitride layer, a silicon oxynitride layer, a silicon oxide layer, a titanium oxide layer, and/or an aluminum oxide layer.

The wavelength conversion layer QDL may convert and/or shift the peak wavelength of incident light into light of another specific peak wavelength and emit it. The wavelength conversion layer QDL may convert the blue first light emitted from the light emitting element LE into red second light, green third light, or transmit the blue first light as it is.

The wavelength conversion layer QDL may be disposed in each light emitting area EA1, EA2, and EA3 (of the subpixels SPX1, SPX2, and SPX3) compartmentalized by the partition wall PW and may be disposed to be spaced from each other. That is, the wavelength conversion layer QDL may be formed in an island pattern spaced from each other. The wavelength conversion layer QDL may be disposed to overlap the first light emitting area EA1, the second light emitting area EA2, and the third light emitting area EA3, respectively. In one or more embodiments, each of the wavelength conversion layers QDL may completely overlap the first light emitting area EA1, the second light emitting area EA2, and the third light emitting area EA3.

The wavelength conversion layer QDL includes a first wavelength conversion pattern WCL1 overlapping with the first light emitting area EA1, a second wavelength conversion pattern WCL2 overlapping with the second light emitting area EA2, and a light transmission pattern TPL overlapping the third light emitting area EA3.

The first wavelength conversion pattern WCL1 may be disposed to overlap the first light emitting area EA1. The first wavelength conversion pattern WCL1 may convert and/or shift the peak wavelength of incident light into light of another specific peak wavelength and emit the light. In one or more embodiments, the first wavelength conversion pattern WCL1 may convert and emit blue first light emitted from the light emitting element LE of the first light emitting area EA1 into second light, which is red light having a single peak wavelength in the range of about 610 nm to about 650 nm.

The first wavelength conversion pattern WCL1 may include a first base resin BRS1, a first wavelength conversion particle WCP1, and a scatterer SCP. The first base resin BRS1 may include a light transmitting organic material. For example, the first base resin BRS1 may include epoxy-based resin, acrylic-based resin, cardo-based resin, and/or imide-based resin.

The first wavelength conversion particle WCP1 may convert the first light incident from the light emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, and/or a phosphorescent material. For example, quantum dots may be particulate materials that emit a specific color as electrons transition from the conduction band to the valence band.

The quantum dots may be semiconductor nanocrystalline materials.

Depending on its composition and size, the quantum dot may have a specific bandgap to absorb light and emit light with a unique wavelength. Examples of the semiconductor nanocrystals of the quantum dots include Group IV nanocrystals, Group II-VI compound nanocrystals, Group III-V compound nanocrystals, Group IV-VI nanocrystals, and/or combinations thereof.

The Group II-VI compound is a binary compound selected from the group consisting of CdSe, CdTe, ZnS, ZnSe, ZnTe, ZnO, HgS, HgSe, HgTe, MgSe, MgS, and mixtures thereof; InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and ternary compounds selected from the group consisting of mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and/or mixtures thereof.

The Group III-V compound is a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAS, AlPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The Group IV-VI compounds may be selected from the group consisting of binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The Group IV element may be selected from the group consisting of Si, Ge, and mixtures thereof. The Group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In one or more embodiments, the quantum dot may have a core-shell structure including a core including a nanocrystal as described above and a shell surrounding the core. The shell of the quantum dot may act as a protective layer to prevent chemical denaturation of the core to maintain semiconductor properties and/or as a charging layer to impart electrophoretic properties to the quantum dot. The shell may be monolayer and/or multilayer. Examples of shells for the quantum dots include oxides of metals or non-metals, semiconductor compounds, and/or combinations thereof.

For example, the oxides of said metals or non-metals may be exemplified by binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or ternary compounds such as MgAl₂O₄, CoFe₂O₄, NiFe₂O₄, CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. but are not limited thereto.

The second wavelength conversion pattern WCL2 may be disposed to overlap the second light emitting area EA2. The second wavelength conversion pattern WCL2 may emit light by converting and/or shifting the peak wavelength of incident light into light of another specific peak wavelength. In one or more embodiments, the second wavelength conversion pattern WCL2 converts the blue first light emitted from the light emitting element LE of the second light emitting area EA2 into green third light having a peak wavelength in the range of about 510 nm to 550 nm and emit it.

The second wavelength conversion pattern WCL2 may be a second base resin BRS2 and a second wavelength conversion particle WCP2 and the scatterer SCP dispersed in the second base resin BRS2.

The second base resin BRS2 may be made of a material with high light transmittance, may be made of the same material as the first base resin BRS1, and/or may include at least one of the materials exemplified as their constituent materials.

The second wavelength conversion particle WCP2 may convert or shift the peak wavelength of incident light to another specific peak wavelength. In one or more embodiments, the second wavelength conversion particle WCP2 may convert the blue first light provided from the light emitting element LE into green third light having a peak wavelength in the range of about 510 nm to 550 nm and emit it. Examples of the second wavelength conversion particle WCP2 include quantum dots, quantum rods, and/or phosphors. A more specific description of the second wavelength conversion particle WCP2 is substantially the same as or similar to that described above in the description of the first wavelength conversion particle WCP1 and will be omitted.

The light transmission pattern TPL may be arranged to overlap the third light emitting area EA3. The light transmission pattern TPL may transmit incident light. The light transmission pattern TPL may directly transmit the blue first light emitted from the light emitting element LE disposed in the third light emitting area EA3. The light transmission pattern TPL may include a third base resin BRS3 and the scatterer SCP dispersed in the third base resin BRS3. Because the third base resin BRS3 is substantially the same as or similar to the above-described first base resin BRS1, description thereof will be omitted. In one or more embodiments, in the light transmission pattern TPL, more scatterers SCP may be disposed compared to the first wavelength conversion particles WCP1 and the second wavelength conversion particles WCP2.

The wavelength control portion 200 may further include a capping layer CAP. The capping layer CAP may be disposed on the wavelength conversion layer QDL and the partition wall PW. The capping layer CAP may include an inorganic material. For example, the capping layer CAP may include at least one of silicon nitride, aluminum nitride, zirconium nitride, titanium nitride, hafnium nitride, tantalum nitride, silicon oxide, aluminum oxide, titanium oxide, tin oxide, cerium oxide, and/or silicon oxide. The drawing illustrates that the capping layer CAP is formed as a single layer, but the present disclosure is not limited thereto. For example, the capping layer CAP may be formed of multiple layers in which inorganic layers containing at least one of the materials that the capping layer CAP may include are alternately stacked. The thickness of the capping layer CAP may range from 0.05 μm to 2 μm but is not limited thereto. The capping layer CAP may be disposed on the top, bottom, and sides of the wavelength conversion layer QDL to be around (e.g., to surround) the wavelength conversion layer QDL to protect the wavelength conversion layer QDL from moisture. The capping layer CAP may be composed of multiple inorganic films with different refractive indices. Alternatively, the camping layer CAP may include an organic film and have a multilayer structure, for example, an inorganic film, an organic film, and/or an inorganic film. Alternatively, the capping layer CAP may also be formed of a low refractive index material that has a lower refractive index than the organic layer. When the capping layer CAP is formed of a low refractive index material, total reflection of light emitted from the light emitting element LE and photo-converted by passing through the wavelength conversion layer QDL may be prevented. This enables the light to be focused upwards. When the capping layer CAP is formed of multiple layers, for example, when it includes a first capping layer and a second capping layer and the wavelength conversion layer QDL has a refractive index of 1.5 to 2.0, at least one of the first capping layer and the second capping layer may have a refractive index between 1.1 and 1.5.

In one or more embodiments, the color filter layer CFL may be disposed on the wavelength control portion 200. The color filter layer CFL may include a first overcoat layer OC1, a first color filter CF1, a second color filter CF2, a third color filter CF3, and a second overcoat layer OC2.

The first overcoat layer OC1 may be disposed on the wavelength control portion 200. The first overcoat layer OC1 may be directly disposed on the capping layer CAP of the wavelength control portion 200. The first overcoat layer OC1 may be disposed entirely over the display area DPA and may have a flat surface. The first overcoat layer OC1 may flatten the step formed by the lower wavelength control portion 200 to facilitate the formation of the color filter layer CFL.

The first overcoat layer OC1 may include a light-transmitting organic material. For example, the first overcoat layer OC1 may include epoxy resin, acrylic resin, cardo resin, and/or imide resin. In one or more embodiments, the first overcoat layer OC1 may be formed of a low refractive index material that has a lower refractive index than the capping layer CAP or the wavelength conversion layer QDL. When the first overcoat layer OC1 has a low refractive index, the light that has been photoconverted through the wavelength conversion layer QDL may be prevented from being reflected by the first overcoat layer OC1, resulting in light being focused upward.

In one or more embodiments, when each light emitting element LE of each sub-pixel SPX is a native LED, the wavelength control portion 200 may be omitted. That is, the color filter layer CFL may be disposed on the light emitting element layer EML.

Alternatively, when each light emitting element LE of each sub-pixel SPX is a native LED, the wavelength control portion 200 may be implemented to include phosphor particles rather than a wavelength conversion material to improve light purity.

The first color filter CF1, the second color filter CF2, and the third color filter CF3 may be disposed on the first overcoat layer OC1.

The first color filter CF1 may be disposed in the first emitting area EA1, the second color filter CF2 may be disposed in the second emitting area EA2, and the third color filter CF3 may be disposed in the third emitting area EA3.

The first color filter CF1, the second color filter CF2, and the third color filter CF3 may include a colorant such as the dye or pigment that absorbs wavelengths other than the corresponding color wavelength. The first color filter CF1 may selectively transmit the second light (e.g., red light) and block or absorb the first light (e.g., blue light) and the third light (e.g., green light). The second color filter CF2 may selectively transmit the third light (e.g., green light) and block or absorb the first light (e.g., blue light) and the second light (e.g., red light). The third color filter CF3 may selectively transmit the first light (e.g., blue light) and block or absorb the second light (e.g., red light) and the third light (e.g., green light). For example, the first color filter CF1 may be a red color filter, the second color filter CF2 may be a green color filter, and the third color filter CF3 may be a blue color filter.

In one or more embodiments, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted to the top of the substrate SUB to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may prevent color distortion due to reflection of external light. Additionally, the first color filter CF1, the second color filter CF2, and the third color filter CF3 may serve to block external light. For example, the first color filter CF1 disposed in the first sub-pixel SPX1 may prevent color mixing by blocking the second color light and the third color light coming from the outside. The color purity of sub-pixels may be improved. The plane area of each of the first color filter CF1, the second color filter CF2, and the third color filter CF3 may be larger than the planar area of each of the plurality of light emitting areas EA1, EA2, and EA3. For example, the first color filter CF1 may be larger than the planar area of the first emitting area EA1. The second color filter CF2 may be larger than the planar area of the second emitting area EA2. The third color filter CF3 may be larger than the planar area of the third emitting area EA3. However, it is not limited thereto, and the planar area of each of the first color filter CF1, the second color filter CF2, and the third color filter CF3 may be equal to the planar area of each of the plurality of light emitting areas EA1, EA2, and EA3. In one or more embodiments, the planar areas of each of the first color filter CF1, second color filter CF2, and third color filter CF3 may be different. For example, the second color filter CF2 may have the largest area, the third color filter CF3 may have the smallest area, and the first color filter CF1 may have an area intermediate between the area of the second color filter CF2 and the area of the third color filter CF3. For example, the first color filter CF1, the second color filter CF2, and the third color filter CF3 may be red, green, and blue, respectively.

The second overcoat layer OC2 may be disposed on the first color filter CF1, the second color filter CF2, and the third color filter CF3. The second overcoat layer OC2 may be directly disposed on the first color filter CF1, the second color filter CF2, and the third color filter CF3. The second overcoat layer OC2 may be disposed entirely in the display area DPA and may have a flat surface. The second overcoat layer OC2 may flatten the step formed by the first color filter CF1, the second color filter CF2, and the third color filter CF3 at the bottom. The second overcoat layer OC2 may include a light-transmitting organic material and may be substantially the same as or similar to the first overcoat layer OC1 described above.

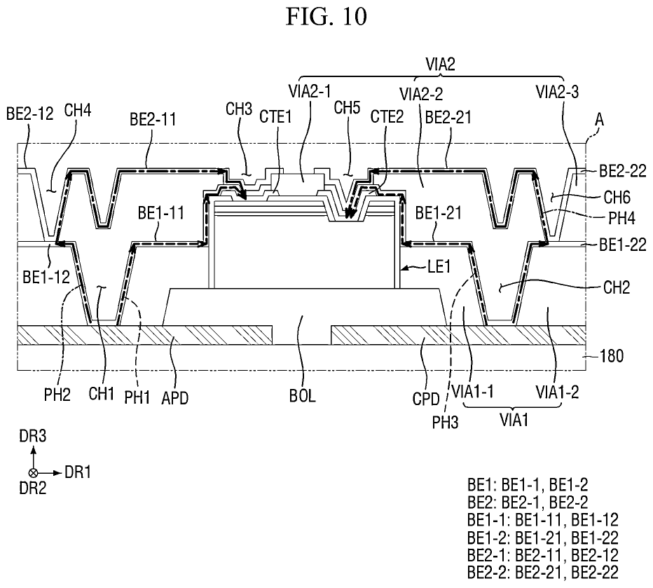

FIG. 10 is a diagram to illustrate a contact path between a first electrode and a first contact electrode in the display panel illustrated with reference to FIG. 7.

Referring to FIG. 10, the first contact electrode CTE1 and the first electrode APD of the first light emitting element LE1 may include the first contact path PH1 through the first lower connection electrode BE1-1 and a second contact path PH2 through the first upper connection electrode BE2-1.

In addition, the second contact electrode CTE2 and the second electrode CPD of the first light emitting element LE1 may include a first contact path PH3 through the second lower connection electrode BE1-2 and a second contact path PH4 through the second upper connection electrode BE2-2.

In this way, when there are two contact paths, one between the first contact electrode CTE1 and the first electrode APD and the other between the second contact electrode CTE2 and the second electrode CPD, it is possible to inject current into the light emitting element LE through the other even if a break occurs in one of the contact paths.

In this way, the first contact electrode CTE1 and the first electrode APD of the first light emitting element LE1 are connected in parallel, and the second contact electrode CTE2 and the second electrode CPD of the first light emitting element LE1 are connected in parallel, there is a resistance reduction effect.

In addition, the generation of outgas may be reduced or minimized, thereby reducing or minimizing the fluttering phenomenon between the light emitting elements LE1, LE2, and LE3 and the first via layer VIA1 by stacking a relatively thin first via layer VIA1 and a second via layer VIA2 rather than a thick single-layer via layer. Therefore, the breakdown of the connection electrodes connecting the light emitting elements LE and the electrodes APD and CPD due to outgassing may be reduced or minimized.

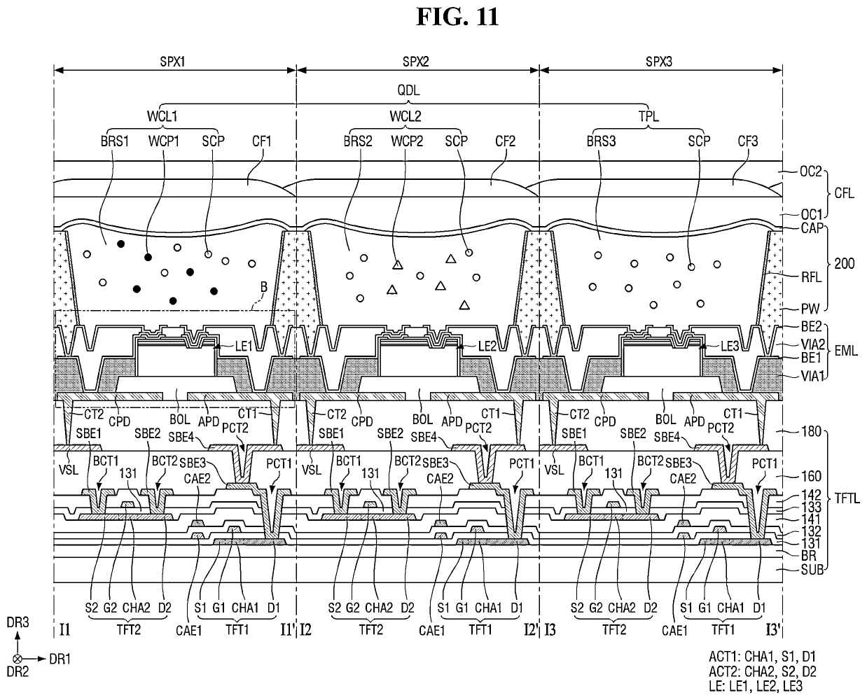

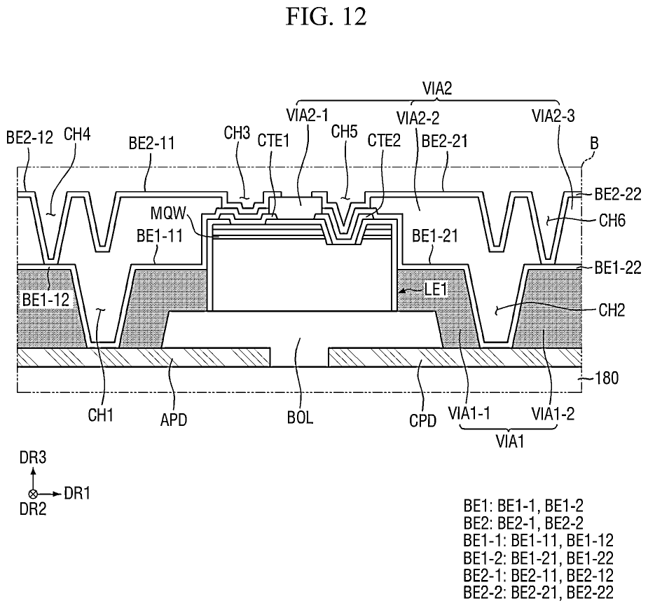

FIG. 11 is a cross-sectional view illustrating another example of a cross-section of the display panel corresponding to the lines I1-I1′, I2-I2′, and I3-I3′ of FIG. 6. FIG. 12 is a cross-sectional view illustrating one example of an area B in FIG. 11 in detail.

The embodiments of FIGS. 11 and 12 are different from the embodiments of FIGS. 7 and 8 in that the first via layer VIA1 includes a light blocking material. In the embodiments of FIGS. 11 and 12, descriptions overlapping with those of FIGS. 7 and 8 are omitted.

The first via layer VIA1 may be formed lower than the active layer MQW of the first light emitting element LE1.

The first via layer VIA1 may be formed of an organic film such as an acrylic resin, an epoxy resin, a phenolic resin, a polyamide resin, a polyimide resin, and/or the like. The height of the first via layer VIA1 may be formed to be lower than that of the first light emitting element LE1. The first via layer VIA may include a light blocking material to prevent light from the light emitting element LE of one sub-pixel from proceeding to the neighboring sub-pixel. For example, the via layer VIA1 may include an inorganic black pigment such as carbon black or an organic black pigment.

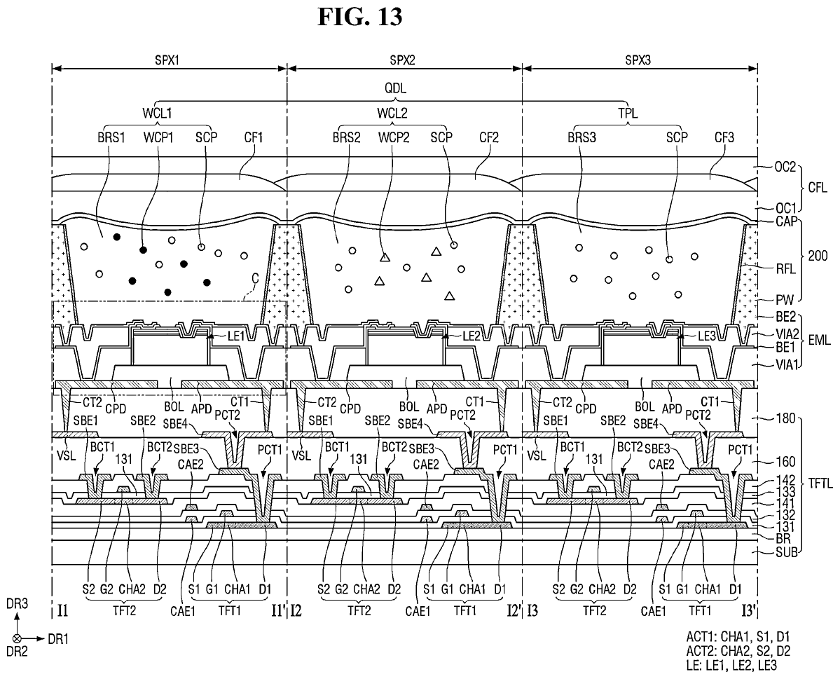

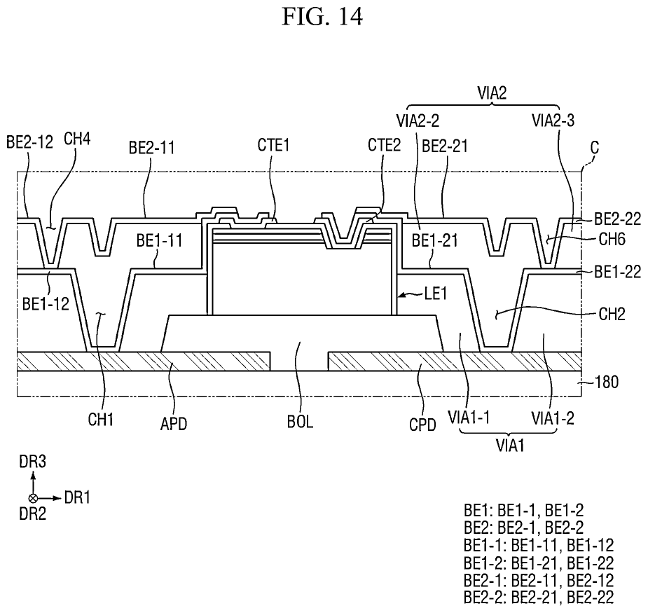

FIG. 13 is a cross-sectional view illustrating another example of a cross-section of a display panel corresponding to the lines I1-I1′, I2-I2′, and I3-I3′ of FIG. 6. FIG. 14 is a cross-sectional view illustrating one example of an area C of FIG. 13 in detail.

The embodiments of FIGS. 13 and 14 are different from the embodiments of FIGS. 7 and 8 in that the second via layer VIA2 does not overlap the first light emitting element LE1. In the embodiments of FIGS. 13 and 14, descriptions overlapping with those of FIGS. 7 and 8 will be omitted.

Referring to FIGS. 7, 8, 13, and 14, the second via layer VIA2 is disposed not to cover the light emitting element LE. The second via layer VIA2 may be arranged to expose the first lower connection electrode BE1-1 and the second lower connection electrode BE1-2, which overlap the first contact electrode CTE1 and the second contact electrode CTE2. Accordingly, the second via layer VIA2 does not have the third connection hole CH3 and the fifth connection hole CH5 shown in FIG. 8. The second via layer VIA2 has the fourth connection hole CH4 and the sixth connection hole CH6.

The fourth connection hole CH4 is formed to be located outside the light emitting element LE than the first connection hole CH1, and the first lower connection electrode BE1-1 exposed by the fourth connection hole CH4 is connected to the first connection hole CH1. The fourth connection hole CH4 may expose the first lower connection electrode BE1-1. The first lower connection electrode BE1-1 exposed by the fourth connection hole CH4 is connected to the first connection hole CH1. Accordingly, the first upper connection electrode BE2-1 disposed on the second via layer VIA2 is connected to the first electrode APD along the first lower connection electrode BE1-1 through the fourth connection hole CH4.

The sixth connection hole CH6 Is formed to be located outside the light emitting element LE than the second connection hole CH2, and the second lower connection electrode BE1-2 exposed by the sixth connection hole CH6 is connected to the second connection hole CH2. The sixth connection hole CH6 may expose the second lower connection electrode BE1-2. The second lower connection electrode BE1-2 exposed by the sixth connection hole CH6 is connected to the second connection hole CH2. Accordingly, the second upper connection electrode BE2-2 disposed on the second via layer VIA2 is connected to the second electrode CPD along the second lower connection electrode BE1-2 through the sixth connection hole CH6.

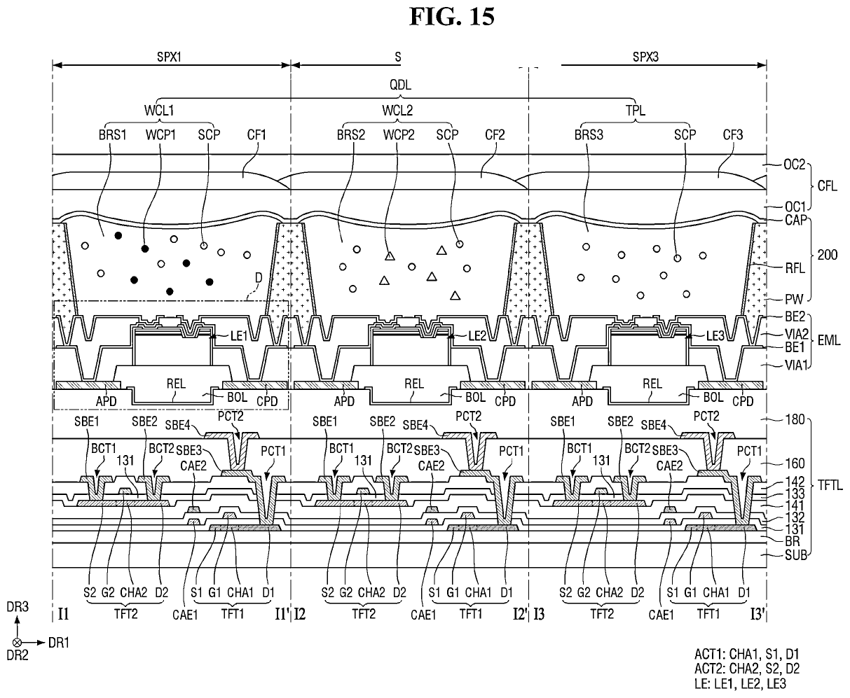

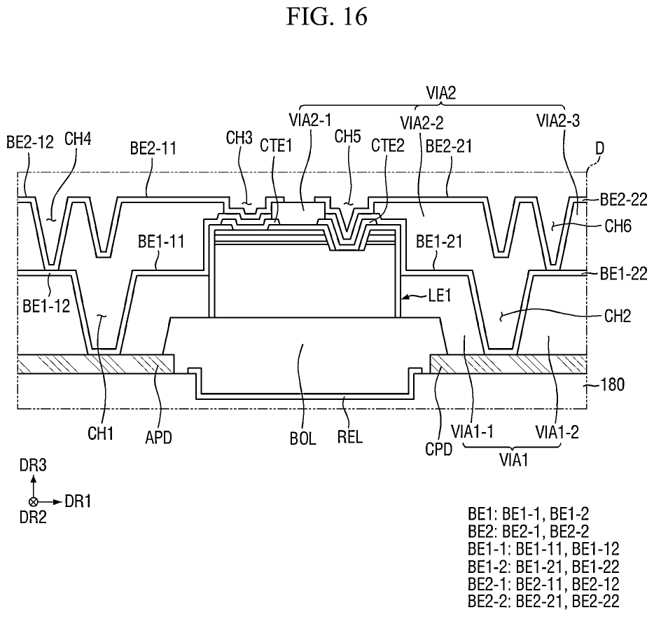

FIG. 15 is a cross-sectional view illustrating another example of a cross-section of a display panel corresponding to the lines I1-I1′, I2-I2′, and I3-I3′ of FIG. 6. FIG. 16 is a cross-sectional view illustrating one example of an area D of FIG. 15.

The embodiment of FIGS. 15 and 16 differs from the embodiment of FIGS. 7 and 8 in that the second organic film 180 has a recess 180-R and a first reflective layer REL is disposed along the recess 180-R. In the embodiments of FIGS. 15 and 16, descriptions overlapping with those of FIGS. 7 and 8 will be omitted.

Referring to FIGS. 7, 8, 13, and 14, the second organic film 180 has a recess 180-R. The recess 180-R may overlap the organic pattern layer BOL (e.g., in the third direction DR3). The recess 180-R may overlap the first light emitting element LE1. The first reflective layer REL may be disposed on the recess 180-R. The first reflective layer RFL may be made of a highly reflective metal material such as aluminum (Al). The first reflective layer REL may reflect light emitted from the first light emitting element LE1 that proceeds in the downward direction of the light emitting element LE1 to proceed in the upward direction of the first light emitting element LE1. Therefore, because light loss from the first light emitting element LE1 may be reduced, the light efficiency of the first light emitting element LE1 may be increased. In one or more embodiments, the first reflective layer REL may be formed as a single layer or multiple layers. For example, the first reflective layer REL may include a first layer and a second layer of M (M is an integer of 2 or more) pairs having different refractive indices, to serve as Distributed Bragg Reflectors (DBR).

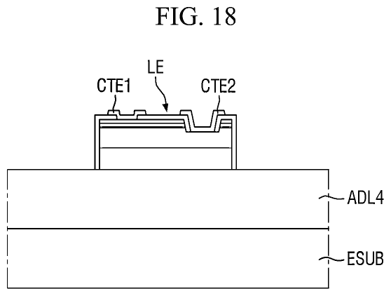

FIG. 17 is a flowchart illustrating a method of manufacturing a display device according to one or more embodiments. FIGS. 18-26 are cross-sectional views to illustrate a method of manufacturing a display device according to one or more embodiments. FIGS. 18-26 illustrate examples of cross sections of the display panel corresponding to the lines 11-11′ in FIG. 6. Some of the drawings in FIGS. 18-26 illustrate plan views corresponding to cross section together. Additionally, the following will focus on the first light emitting area EA1 of the display device 10.

First, as shown in FIG. 18, a plurality of light emitting elements LE disposed on a light emitting element substrate ESUB are prepared (S110 in FIG. 17).

The first light emitting element LE1 is disposed on a fourth adhesive layer ADL4 disposed on the light emitting element substrate ESUB. The plurality of light emitting elements LE are fixed by adhesion to the fourth adhesive layer ADL4. The light emitting element substrate ESUB may include a material that allows light to be transmitted. For example, the light emitting element substrate ESUB may include transparent polymers such as polyimide, polyester, polyacrylic, polyepoxy, polyethylene, polystyrene, polyethylene terephthalate, and/or the like. The fourth adhesive layer ADL4 may include an adhesive material for bonding the plurality of light emitting elements LE. For example, the adhesive material may include urethane acrylate, epoxy acrylate, polyester acrylate, and/or the like.

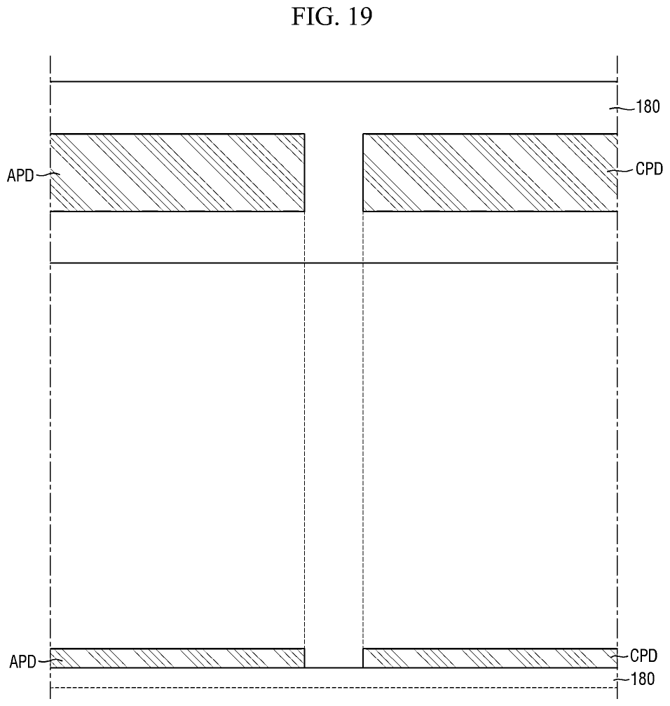

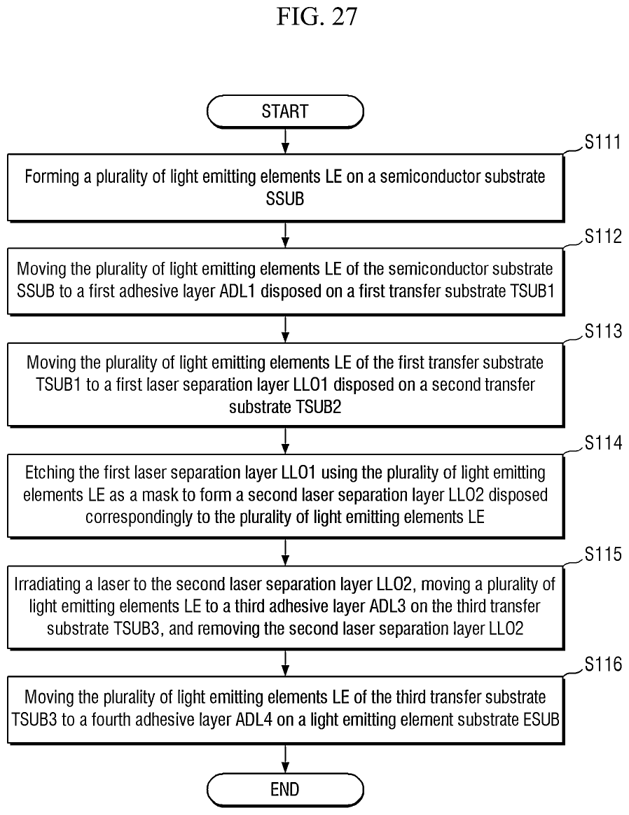

A detailed description of a method of transferring the plurality of light emitting elements LE formed on the semiconductor substrate SSUB onto the light emitting element substrate ESUB will be described later with reference to FIGS. 27-34. To facilitate understanding of the description, FIGS. 19-21 illustrate a plan view of the drawing corresponding to a side view of the drawing. In FIGS. 19-21, the drawing disposed on the upper side is a shape viewed from the top of the side view disposed on the lower side.

Second, as shown in FIG. 19, a first electrode APD and a second electrode CPD are formed on the substrate SUB having a thin film transistor layer (TFTL in FIG. 7) using a mask (S120 in FIG. 17).

A layer of electrode material is applied on the substrate having the thin film transistor layer. Afterwards, the first electrode APD and the second electrode CPD are formed on the same plane and spaced from each other using a photolithography process.

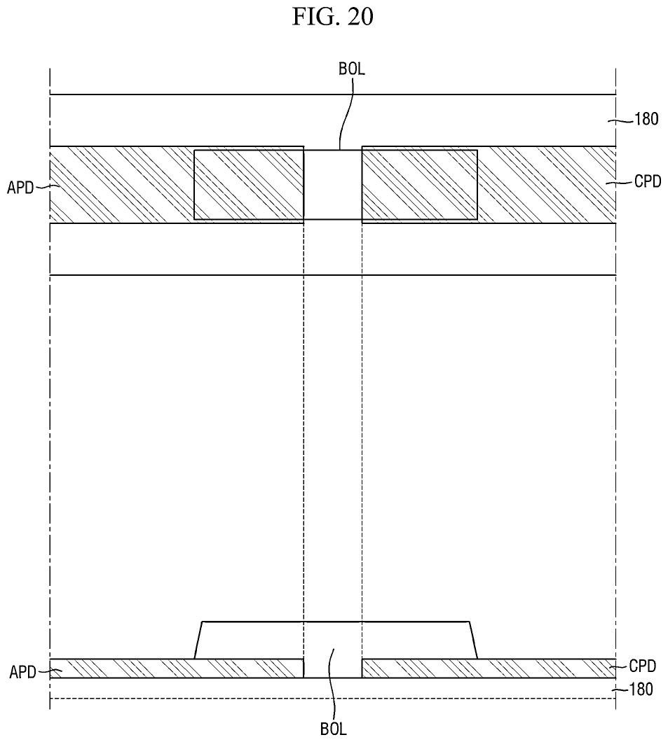

Third, as shown in FIG. 20, an organic pattern layer BOL is formed on the first electrode APD and the second electrode CPD (S130 in FIG. 17).

The organic pattern layer BOL is formed between the first electrode APD and the second electrode CPD. The organic pattern layer BOL is formed to cover the edges of the first electrode APD and the edges of the second electrode CPD. The organic pattern layer BOL may be filled in the space between the first electrode APD and the second electrode CPD. The organic pattern layer BOL may be formed to be thicker than the height of the first electrode APD and the second electrode CPD. The organic pattern layer BOL may be formed by applying a material to the entire surface using a photolithography process and then using a mask or the like. Alternatively, the organic pattern layer BOL may be applied in a patterned manner using printing or inkjet.

The organic pattern layer BOL may be a temporary adhesive layer, a temporary adhesive layer, or a temporary fixation layer that serves to temporarily fix or adhere a plurality of light emitting elements LE in the process of transferring the light emitting elements LE to the display panel 100.

The organic pattern layer BOL may be a photosensitive organic film such as photoresist. Alternatively, the organic pattern layer BOL may be formed of acryl resin, epoxy resin, phenolic resin, polyamide resin, polyimide resin, and/or the like.

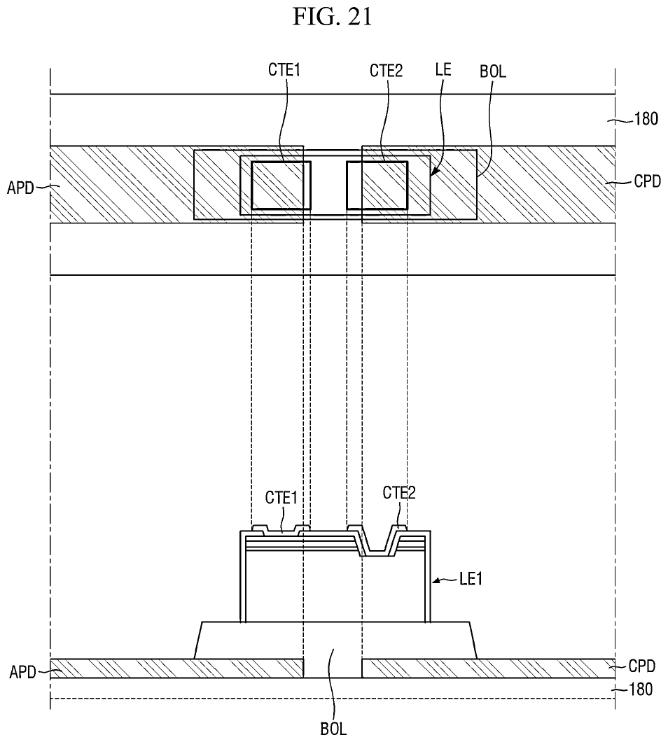

Fourth, as shown in FIG. 21, a plurality of light emitting elements LE of the light emitting element substrate ESUB are fixed to the organic pattern layer BOL (S140 in FIG. 17).

The light emitting element LE on the light emitting element substrate ESUB is disposed on the organic pattern layer BOL. The light emitting element LE is disposed so that the first contact electrode CTE1 and the second contact electrode CTE2 are facing the upper surface. The first contact electrode CTE1 may be disposed close to the first electrode APD, and the second contact electrode CTE2 may be disposed close to the second electrode CPD.

At this time, the plurality of light emitting elements LE may be temporarily fixed by being embedded in the organic pattern layer BOL. For example, the third semiconductor layer SEM3 of each of the plurality of light emitting elements LE may be embedded in the organic pattern layer BOL and fixed.

If the organic pattern layer BOL is a photosensitive organic film such as a photoresist, the organic pattern layer BOL may be cured (soft baked) at a first temperature, and then at least a portion of the light emitting element LE may be inserted into the organic pattern layer BOL. Then, the organic pattern layer BOL may be completely cured at a second temperature higher than the first temperature. The first temperature may be approximately 100 degrees, and the second temperature may be approximately 230 degrees, but the present disclosure is not limited thereto. In the process of curing the organic pattern layer BOL at the first temperature, the organic pattern layer BOL may be fluid because the first temperature is low enough to fully cure the organic pattern layer BOL. If the organic pattern layer BOL spreads over a larger area than desired, it may be formed into the desired shape by etching or ashing after an additional curing process to be described later. Furthermore, the process of completely curing the organic pattern layer BOL at the second temperature may be performed for approximately 30 minutes.

Then, the light emitting element substrate ESUB is separated from the light emitting element LE. For example, ultraviolet light or heat may be applied to the adhesive layer of the light emitting element substrate ESUB to reduce the adhesion of the adhesive layer of the light emitting element substrate ESUB, and then the light emitting element substrate ESUB may be physically or naturally separated from the plurality of light emitting elements LE.

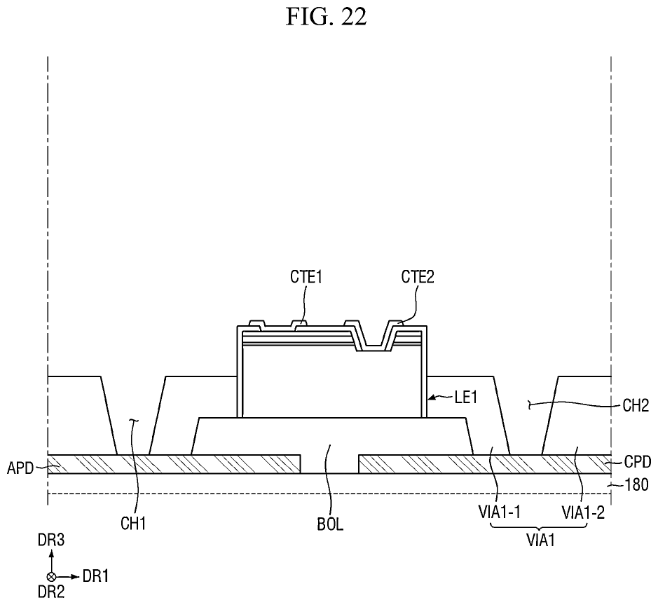

Next, referring to FIG. 22, a first via layer VIA1 is formed to cover the organic pattern layer BOL and have a first connection hole CH1 and a second connection hole CH2 (S150 in FIG. 17).

The first via layer VIA1 may be formed lower than the height of the active layer MQW of the light emitting element LE. The first via layer VIA1 may be applied using a solution process such as spin coating, inkjet printing, or the like.

Next, a plurality of connection holes CH1 and CH2 are formed in the first via layer VIA1 through an etching process using a mask.

The first connection hole CH1 exposes the first electrode APD on the first electrode APD, and the second connection hole CH2 exposes the second electrode CPD on the second electrode CPD.

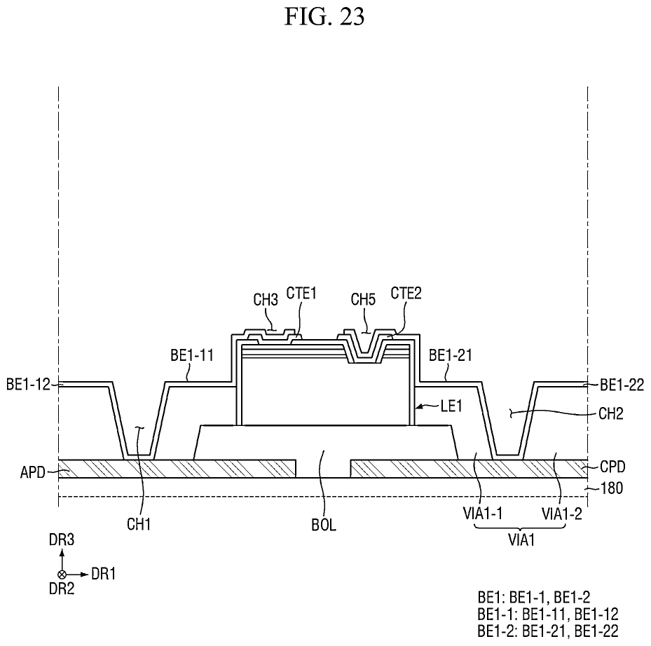

Next, referring to FIG. 23, the first lower connection electrode BE1-1 and the second lower connection electrode BE1-2 are formed on the first via layer VIA1 (S160 in FIG. 17).

The first lower connection electrode BE1-1 connects the first contact electrode CTE1 and the first electrode APD of the light emitting element LE disposed on the organic pattern layer BOL in each of the sub-pixels SPX1 to SPX4. For example, a lower connection electrode material is deposited on the light emitting element LE and the first via layer VIA1. Thereafter, a first lower connection electrode BE1-1 and a second lower connection electrode BE1-2 that are spaced from each other are formed using a photoresist technique using a mask.

The first lower connection electrode BE1-1 contacts the first electrode APD exposed by the first connection hole CH1, and the second lower connection electrode BE1-2 contacts the second electrode CPD exposed by the second connection hole CH2.

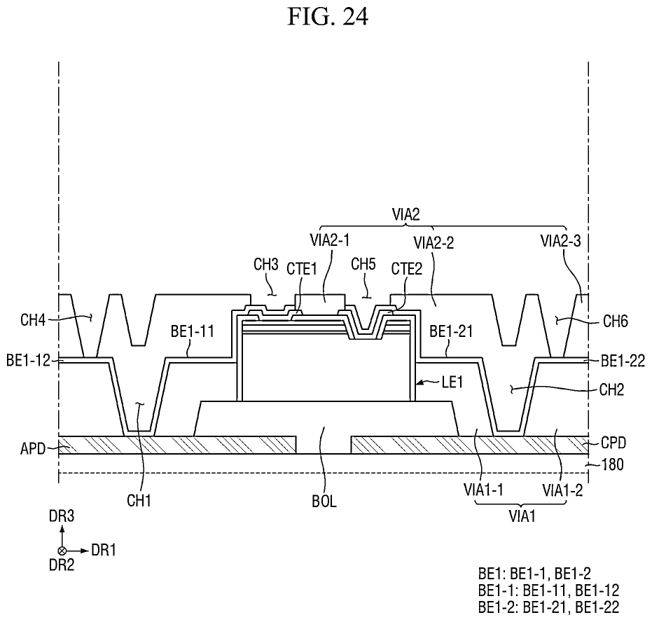

Sixth, reference to FIG. 24, a second via layer VIA2 having a plurality of connection holes CH3, CH4, CH5, and CH6 is formed on the first via layer VIA1 (S170 in FIG. 17).

The second via layer VIA2 may be formed to completely cover the light emitting element LE. The second via layer VIA2 may be applied using a solution process such as spin coating, inkjet printing, and/or the like.

Next, connection holes CH3, CH4, CH5, and CH6 are formed in the second via layer VIA2 by an etching process using a mask.

The third connection hole CH3 overlaps the first contact electrode CTE1 and exposes the first lower connection electrode BE1-1, and the fifth connection hole CH5 overlaps the second contact electrode CTE2 and exposes the second lower connection electrode BE1-2. The fourth connection hole CH4 is formed to be located outside the light emitting element LE than the first connection hole CH1, and the first lower connection electrode BE1-1 exposed by the fourth connection hole CH4 is connected with the first connection hole CH1. The fourth connection hole CH4 may expose the first lower connection electrode BE1-1. The first lower connection electrode BE1-1 exposed by the fourth connection hole CH4 is connected to the first connection hole CH1.

The sixth connection hole CH6 Is formed to be located outside the light emitting element LE than the second connection hole CH2, and the second lower connection electrode BE1-2 exposed by the sixth connection hole CH6 is connected with the second connection hole CH2. The sixth connection hole CH6 may expose the second lower connection electrode BE1-2. The second lower connection electrode BE1-2 exposed by the sixth connection hole CH6 is connected to the second connection hole CH2.

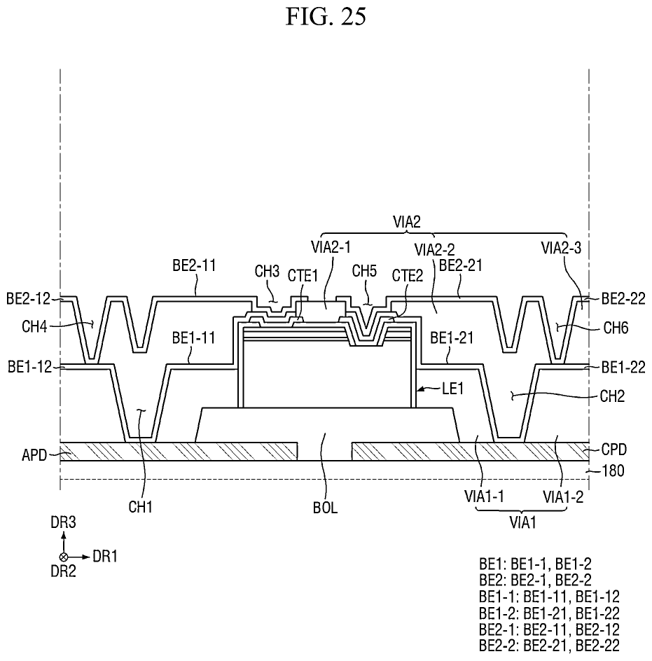

Next, referring to FIG. 25, the first upper connection electrode BE2-1 and the second upper connection electrode BE2-2 are formed on the second via layer VIA2 (S180 in FIG. 17).

An upper connection electrode material layer is deposited on the second via layer VIA2. Then, the first upper connection electrode BE2-1 and the second upper connection electrode BE2-2 that are spaced from each other are formed using a photoresist technique using a mask.

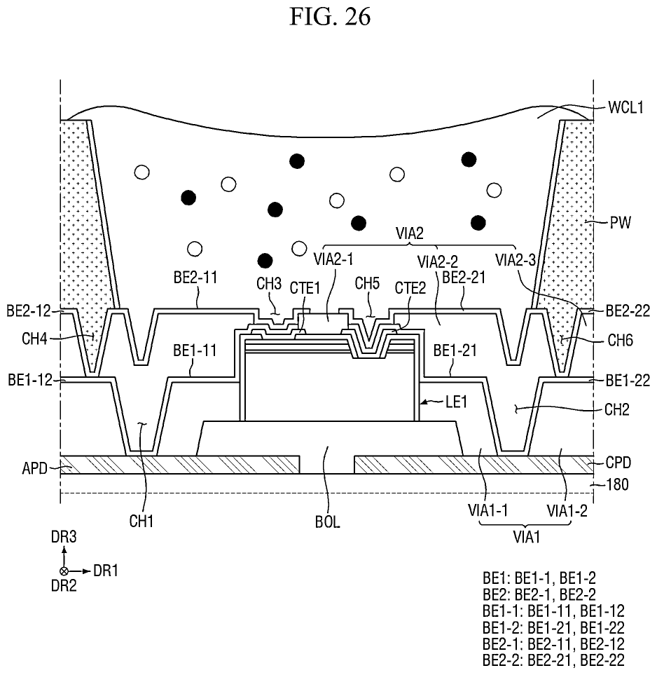

Next, referring to FIG. 26, a partition wall PW, a wavelength conversion layer WCL1, and a light transmission layer TCP are formed. Furthermore, a color filter layer (CFL in FIG. 7) may be further formed (S190 in FIG. 17).

First, an organic material is applied to the second via layer VIA2 and patterned to form a partition wall PW. A second reflective layer RFL may be formed on the inner surface of the space formed by the partition wall PW.

Then, the partition wall PW has an opening and a wavelength conversion layer WCL1 is formed in the opening. Among the areas compartmentalized by the partition wall PW, a first wavelength conversion layer WCL1 is formed in the first sub-pixel SPX1, a second wavelength conversion layer WCL2 is formed in the second sub-pixel SPX2, and a light transmission layer TCP is formed in the third sub-pixel SPX3.

Then, the first overcoat layer OC1, first color filter CF1, second color filter CF2, third color filter CF3, and second overcoat layer OC2 described in FIG. 7 may be formed on the partition wall PW, wavelength conversion layer WCL1 and WCL2, and light transmission layer TCP.

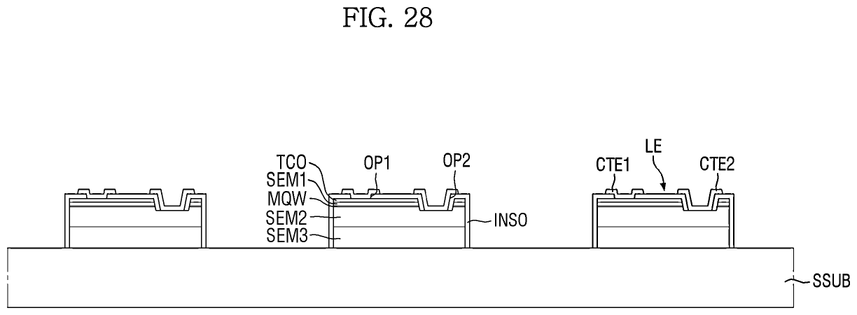

FIG. 27 is a flowchart illustrating step S110 of FIG. 17 in detail. FIGS. 28-34 are cross-sectional views to illustrate step S110.

Hereinafter, the process of transferring the plurality of light emitting elements LE formed on the semiconductor substrate SSUB to the light emitting element substrate ESUB will be described in detail with reference to FIGS. 27-34.

First, a plurality of light emitting elements LE are formed on the semiconductor substrate SSUB as shown in FIG. 28. (S111 in FIG. 27).

The semiconductor substrate SSUB may be a silicon wafer substrate or a sapphire substrate. A light emitting element material layer is deposited on the entire semiconductor substrate SSUB. The light emitting element material layer may be formed on the semiconductor substrate SSUB through an epitaxial growth process. As the epitaxial growth process, the methods of forming the light emitting element material layer may include electron beam deposition, physical vapor deposition (PVD), chemical vapor deposition (CVD), plasma laser deposition (PLD), dual-type thermal evaporation, sputtering, metal organic chemical vapor deposition (MOCVD), and the like. Preferably, metal-organic chemical vapor deposition (MOCVD) may be used, but the present disclosure is not limited thereto.

Next, a transparent conductive material layer is formed on the light emitting element material layer. Then, the plurality of semiconductor material layers and the transparent conductive material layer are etched. As shown in FIG. 9, the light emitting element material layer may include a third semiconductor layer SEM3, a second semiconductor layer SEM2, an active layer MQW, a first semiconductor layer SEM1, a transparent conductive layer TCO, a first contact electrode CTE1, a second contact electrode CTE2, and an element insulating layer INS0.

Then, after forming a mask pattern on the light emitting element material layer, the light emitting element material layer and the transparent conductive material layer may be etched according to the mask pattern to form the plurality of light emitting elements LE. The mask pattern may be removed after forming the plurality of light emitting elements LE.

The light emitting element material layer may be etched by dry etching, wet etching, reactive ion etching (RIE), deep reactive ion etching (DRIE), inductively coupled plasma reactive ion etching (ICP-RIE), and/or the like. The dry etching allows for anisotropic etching and may be suitable for vertical etching. In the case of dry etching, the etching gas may be Cl₂ or O₂, but is not limited thereto.

Then, an opening exposing the second semiconductor layer SEM2 on the transparent conductive layer TCO is formed by an etching process. As described above, the etching process may be a dry etching method, a wet etching method, a reactive ion etching (RIE) method, a deep reactive ion etching (DRIE) method, an inductively coupled plasma reactive ion etching (ICP-RIE) method, and/or the like.

Next, an insulating material layer having a plurality of openings OP1 and OP2 is formed on the base substrate BSUB on which the light emitting element LE is formed.

Then, a second etch (2^{nd} etch) is performed to partially remove the insulating material layer to form the light emitting element LE including an element insulating layer INS0.

Specifically, a second etch (2^{nd} etch) process may be performed in which the insulating material layer is partially removed such that the insulating material layer exposes the top surface of the light emitting element LE but surrounds the sides of the light emitting element LE. Specifically, in this process, the insulating material layer may remove at least a portion of the top surface of the transparent conductive layer TCO of the light emitting element LE to define a first opening OP1.

Further, the insulating material layer may define the second opening OP2 by removing at least a portion of the second semiconductor layer SEM2 of the light emitting element LE. The process of partially removing the insulating material layer may be performed by an etching process using a mask.

Next, a first contact electrode CTE1 in the first opening OP1 and a second contact electrode CTE2 in the second opening OP2 are formed on the light emitting element LE.

For example, the first contact electrode CTE1 and the second contact electrode CTE2 are formed by laminating a contact electrode material layer on the base substrate BSUB. Afterwards, the contact electrode material layer is etched by an etching process to form the first contact electrode CTE1 covering the first opening OP1 of the light emitting element LE and the second contact electrode CTE2 covering the second opening OP2. The contact electrode material layer may be formed of a transparent conductive material. For example, the contact electrode material layer may be a transparent conductive oxide such as indium tin oxide (ITO) and/or indium zinc oxide (IZO).

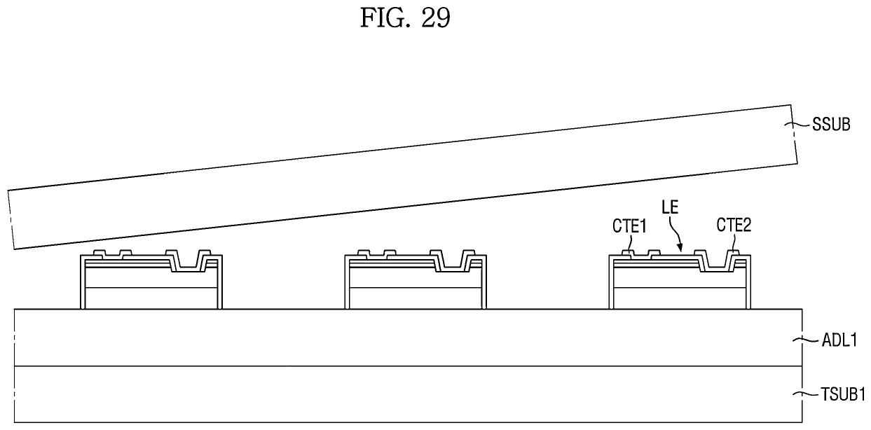

Second, as shown in FIG. 29, the plurality of light emitting elements LE of the semiconductor substrate SSUB are moved to a first adhesive layer ADL1 disposed on a first transfer substrate TSUB1 (S112 in FIG. 27).

The first transfer substrate TSUB1 may be made of a transparent material to allow light to pass through. For example, the first transfer substrate TSUB1 may include a transparent polymer such as polyimide, polyester, polyacrylic, polyepoxy, polyethylene, polystyrene, polyethylene terephthalate, and/or the like. The first adhesive layer ADL1 disposed on one surface of the first transfer substrate TSUB1 may include an adhesive material for bonding the plurality of light emitting elements LE. For example, the adhesive material may include urethane acrylate, epoxy acrylate, polyester acrylate, and/or the like.

The first contact electrode CTE1 and the second contact electrode CTE2 of each of the plurality of light emitting elements LE may be bonded to the first adhesive layer ADL1 disposed on the first transfer substrate TSUB1. Then, the plurality of light emitting elements LE may be separated from the semiconductor substrate SSUB by a laser lift off (LLO) process in which the semiconductor substrate (SSUB) is irradiated with a laser. The laser may be a KrF excimer laser having a wavelength of approximately 248 nm, but the present disclosure is not limited thereto.

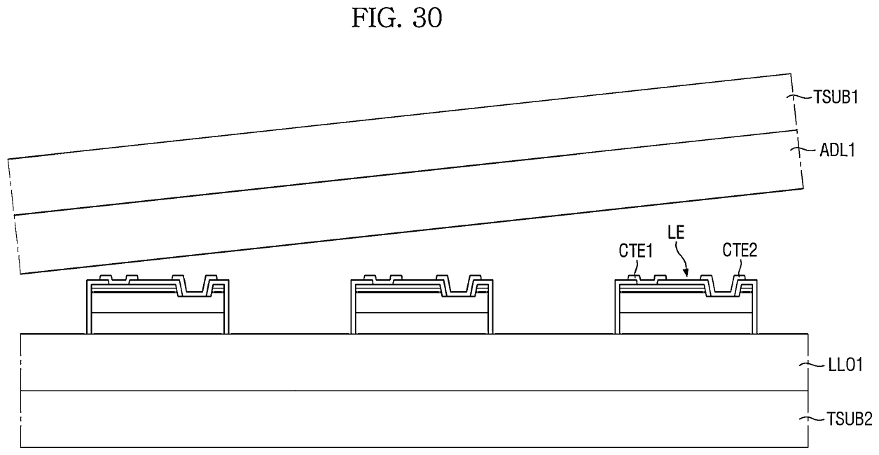

Third, as shown in FIG. 30, the plurality of light emitting elements LE of the first transfer substrate TSUB1 are moved to a first laser separation layer LLO1 disposed on a second transfer substrate TSUB2 (S113 in FIG. 27).

The second transfer substrate TSUB2 may be made of a transparent material to allow light to pass through. For example, the second transfer substrate TSUB2 may include a transparent polymer such as polyimide, polyester, polyacrylic, polyepoxy, polyethylene, polystyrene, polyethylene terephthalate, and/or the like. The first laser separation layer LLO1 disposed on the second transfer substrate TSBU2 is a layer separable by laser irradiation, and may include, for example, a transparent polymer such as polyimide.

When heat is applied while one surface of each of the plurality of light emitting elements LE is in contact with the first laser separation layer LLO1, each of the plurality of light emitting elements LE may be adhered or fixed to the first laser separation layer LLO1, and each of the plurality of light emitting elements LE may be separated from the first adhesive layer ADL1 as the adhesive force of the first adhesive layer ADL1 weakens. One surface of each of the plurality of light emitting elements LE may be opposite to the other surface on which the first contact electrode CTE1 and the second contact electrode CTE2 are disposed in each of the plurality of light emitting elements LE.

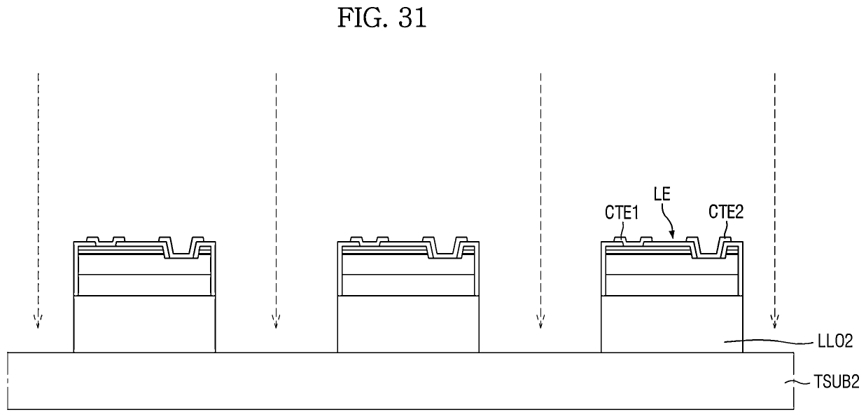

Fourth, as shown in FIG. 31, the first laser separation layer LLO1 is etched using the plurality of light emitting elements LE as a mask to form a second laser separation layer LLO2 disposed correspondingly to the plurality of light emitting elements LE (S114 in FIG. 27).

The plurality of light emitting elements LE are not etched but are dry-etched using etching gas (DEG) in which only the first laser separation layer LLO1 is etched. That is, the first laser separation layer LLO1 is etched using the plurality of light emitting elements LE as a mask. As a result, the first laser separation layer LLO1 that does not overlap the plurality of light emitting elements LE in the thickness direction of the second transfer substrate TSUB2 may be removed. Accordingly, the second laser separation layer LLO2 may be formed overlapping the plurality of light emitting elements LE in the thickness direction of the second transfer substrate TSUB2. The second laser separation layer LLO2 may be disposed between each of the plurality of light emitting elements LE and the second transfer substrate TSUB2 in the thickness direction of the second transfer substrate TSUB2.

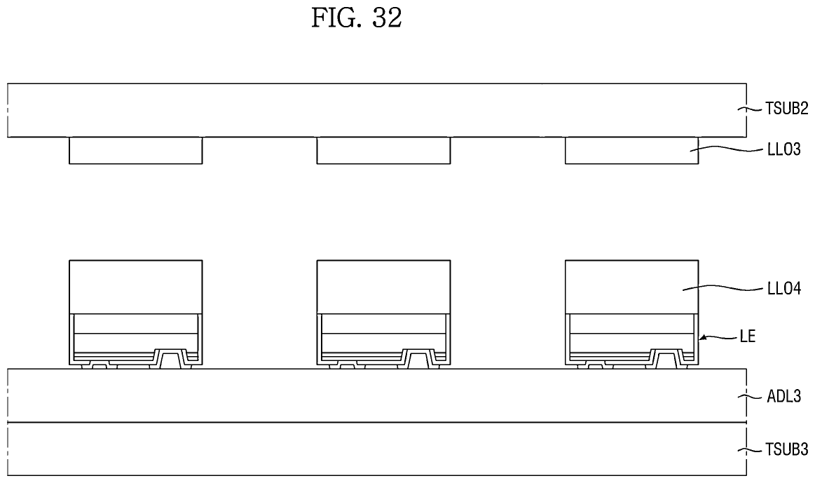

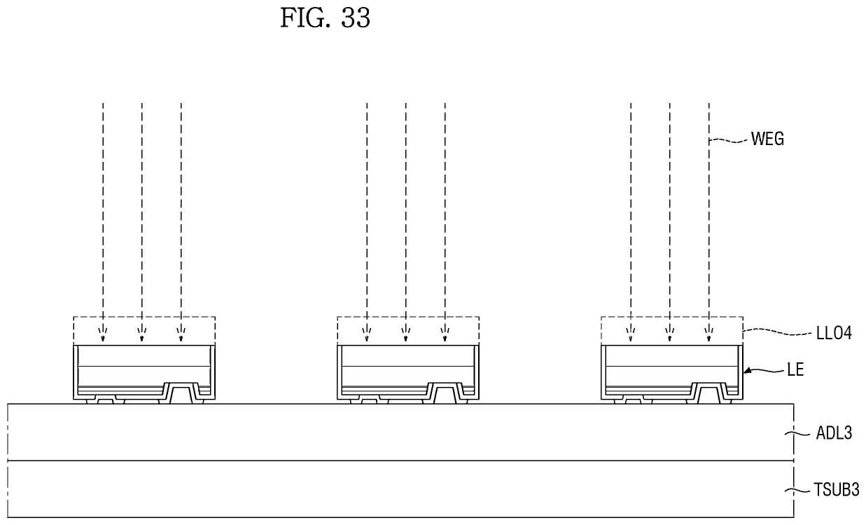

Fifth, as shown in FIGS. 32 and 33, the plurality of light emitting elements LE are transferred to a third adhesive layer ADL3 on a third transfer substrate TSUB3 by irradiating the second laser separation layer LLO2 with a laser and the second laser separation layer LLO2 is removed (S115 in FIG. 27).

The third transfer substrate TSUB3 may be made of a transparent material to allow light to pass through. For example, the third transfer substrate TSUB3 may include a transparent polymer such as polyimide, polyester, polyacrylic, polyepoxy, polyethylene, polystyrene, polyethylene terephthalate, and/or the like. The third adhesive layer ADL3 disposed on one surface of the third transfer substrate TSUB3 may include an adhesive material for bonding the plurality of light emitting elements LE. For example, the adhesive material may include urethane acrylate, epoxy acrylate, polyester acrylate, and/or the like.

When the first contact electrode CTE1 and the second contact electrode CTE2 of each of the plurality of light emitting elements LE are contacted with the third adhesive layer ADL3 on the third transfer substrate TSUB3 and a laser is irradiated onto the second laser separation layer LLO2, the second laser separation layer LLO2 may be separated into a third laser separation layer LLO3 disposed on one surface of the second transfer substrate TSUB2 and a fourth laser separation layer LLO4 disposed on each of the plurality of light emitting elements LE. Then, the fourth laser separation layer LLO4 remaining on each of the plurality of light emitting elements LE may be removed by a wet etching process. The plurality of light emitting elements LE are not etched, and the fourth laser separation layer LLO4 is etched using an etching material WEG in which only the fourth laser separation layer LLO4 is etched. In one or more embodiments, the adhesive layers ADL1, ADL2, and ADL3 are divided into two laser separation layers by laser irradiation so that one laser separation layer remains on the relay substrate and the other laser separation layer is disposed on the light emitting element LE but is not limited thereto. For example, the adhesive layers ADL1, ADL2, and ADL3 may be left on either the relay substrate or the light emitting element LE after laser irradiation, while the other may be removed entirely. For example, when the second laser separation layer LLO2 is irradiated while the light emitting elements LE are in contact with the third adhesive layer ADL3 on the third transfer substrate TSUB3, the second laser separation layer LLO2 may be disposed on one surface of the second transfer substrate TSUB2 and not left on the other side of the light emitting elements LE. In such a case, the wet etching process remaining on the light emitting element LE may be omitted.

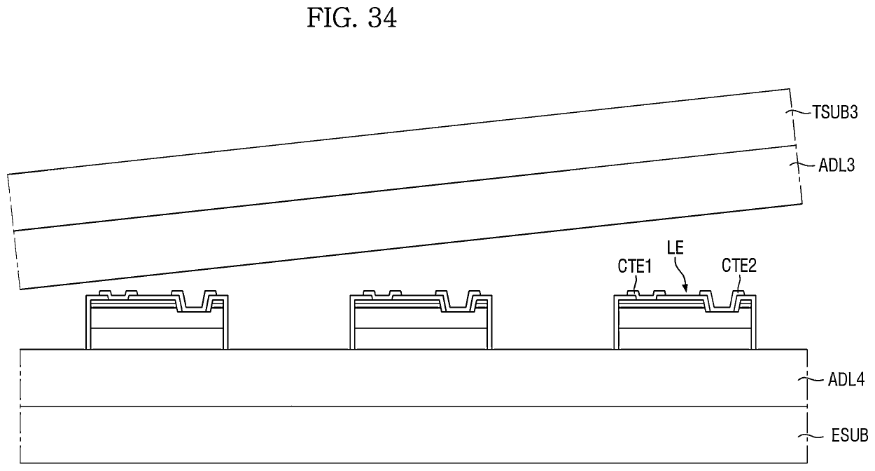

Sixth, as shown in FIG. 34, the plurality of light emitting elements LE of the third transfer substrate TSUB3 are moved to the fourth adhesive layer ADL4 on the light emitting element substrate ESUB (S116 in FIG. 27).

Separate each of the plurality of light emitting elements LE from the third adhesive layer ADL3 while contacting one surface of each of the plurality of light emitting elements LE of the third transfer substrate TSUB3 to the fourth adhesive layer ADL4 on the light emitting element substrate ESUB. In this case, the adhesive force of the fourth adhesive layer ADL4 may be higher than that of the third adhesive layer ADL3. One surface of each of the plurality of light emitting elements LE may be opposite to the other surface of each of the plurality of light emitting elements LE on which the first contact electrode CTE1 and the second contact electrode CTE2 are disposed.

In one or more embodiments, an example in which a final interposer substrate is prepared by arranging the first contact electrode CTE1 and the second contact electrode CTE2 facing upward on the light emitting element substrate ESUB as shown in FIG. 34 is described, but the light emitting elements LE disposed on the final interposer substrate thus prepared may be used when transferred to the target substrate using a stamp. In one or more embodiments, if it is desired to align and transfer the light emitting elements LE of the final interposer substrate on the target substrate without using a stamp, the third transfer substrate TSUB3 of FIG. 33 may become the light emitting element substrate ESUB as the final interposer. In such a case, the step S116 described with reference to FIG. 34 may be omitted.

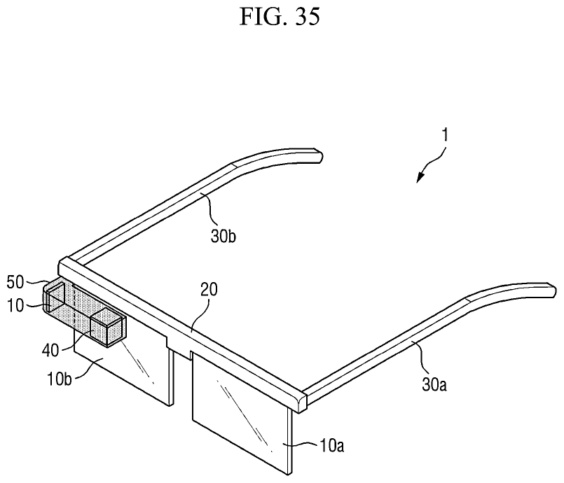

FIG. 35 is an example diagram illustrating a virtual reality device including a display device according to one or more embodiments. FIG. 35 illustrates a virtual reality device 1 in which the display device 10 according to one or more embodiments is used.

Referring to FIG. 35, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 35 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 35, and may be applied in various forms and in various electronic devices.

The display device housing 50 may be the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 35 illustrates that the display device housing 50 is disposed at a right end of the support frame 20. However, the present disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

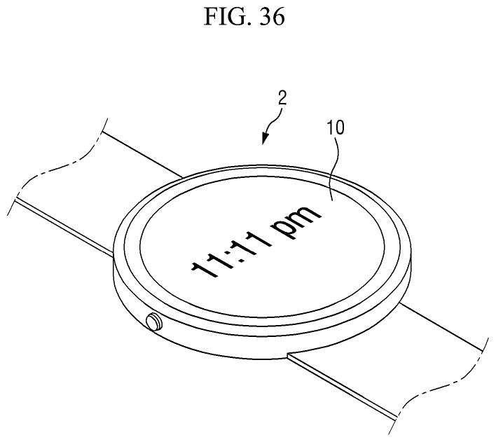

FIG. 36 is an example diagram illustrating a smart device including a display device according to one or more embodiments.

Referring to FIG. 36, a display device 10 according to one or more embodiments may be applied to a smart watch 2 as one of smart devices.

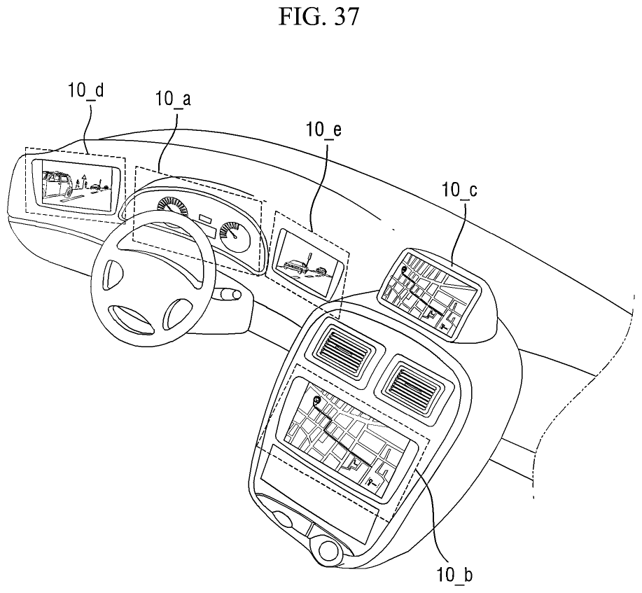

FIG. 37 is an example diagram illustrating a vehicle including a display device according to one or more embodiments. FIG. 37 illustrates a vehicle in which display devices according to one or more embodiments are used.

Referring to FIG. 37, the display devices 10_a, 10_b, and 10_c according to one or more embodiments may be applied to the dashboard of the vehicle, applied to the center fascia of the vehicle, or applied to a Center Information Display (CID) disposed on the dashboard of the vehicle. Further, each of the display devices 10_d and 10_e according to one or more embodiments may be applied to each room mirror display that replaces each of side-view mirrors of the vehicle.

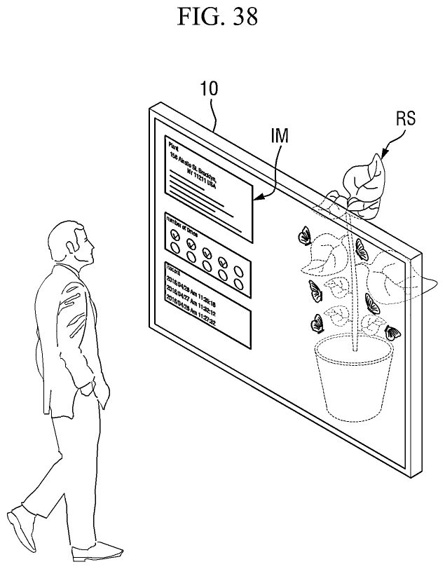

FIG. 38 is an example diagram illustrating a transparent display device including a display device according to one or more embodiments.

Referring to FIG. 38, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the semiconductor substrate SSUB of the display device 10 shown in FIG. 7 may include a light transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a substrate;
a first electrode and a second electrode on the substrate and spaced from each other;
an organic pattern layer between the first electrode and the second electrode;
a light emitting element on the organic pattern layer and having a first contact electrode and a second contact electrode on a top surface;
a first via layer covering the first electrode and the second electrode and covering a portion of a side surface of the light emitting element;
a first lower connection electrode connecting the first electrode and the first contact electrode on the first via layer, and a second lower connection electrode connecting the second electrode and the second contact electrode;
a second via layer on the first via layer and covering a portion of a side surface of the light emitting element; and
a first upper connection electrode connecting the first electrode and the first contact electrode on the second via layer, and a second upper connection electrode connecting the second electrode and the second contact electrode.

2. The display device of claim 1, wherein the first via layer includes a first connection hole and a second connection hole,
wherein the first connection hole exposes the first electrode, and the second connection hole exposes the second electrode.

3. The display device of claim 2, wherein the first lower connection electrode is in contact with the first electrode through the first connection hole, and the second lower connection electrode is in contact with the second electrode through the second connection hole.

4. The display device of claim 3, wherein the second via layer includes a third connection hole and a fourth connection hole, the third connection hole exposes the first lower connection electrode connected to the first electrode, the fourth connection hole exposes the second lower connection electrode connected to the second electrode, the third connection hole and the fourth connection hole are farther from the light emitting element than the first connection hole and the second connection hole.

5. The display device of claim 4, wherein the first upper connection electrode is in contact with the first lower connection electrode through the third connection hole, and the second upper connection electrode is in contact with the second lower connection electrode through the fourth connection hole.

6. The display device of claim 1, wherein the first lower connection electrode is between the first contact electrode and the first upper connection electrode on the light emitting element, and
wherein the second lower connection electrode is between the second contact electrode and the second upper connection electrode on the light emitting element.

7. The display device of claim 1, wherein the light emitting element comprises:
a third semiconductor layer on the organic pattern layer;
a second semiconductor layer on the third semiconductor layer;
an active layer on the second semiconductor layer;
a first semiconductor layer on the active layer; and
an element insulating layer around the light emitting element,
wherein the first contact electrode and the second contact electrode are on the first semiconductor layer, the first contact electrode is connected to the first semiconductor layer, and the second contact electrode is connected to the second semiconductor layer.

8. The display device of claim 7, wherein the first via layer is lower than the active layer.

9. The display device of claim 8, wherein a height of the second via layer is equal to or higher than a height of the light emitting element.

10. The display device of claim 9, wherein the second via layer comprises a fifth connection hole overlapping the first contact electrode of the light emitting element and exposing the first lower connection electrode, and a sixth connection hole overlapping the second contact electrode and exposing the second lower connection electrode.

11. The display device of claim 10, wherein the first upper connection electrode is in contact with the first lower connection electrode through the fifth connection hole, and the second upper connection electrode is in contact with the second lower connection electrode through the sixth connection hole.

12. The display device of claim 8, wherein the first via layer comprises a light blocking material.

13. The display device of claim 1, wherein the first electrode and the second electrode are spaced from each other on a same plane and protrude outward from the light emitting element.

14. The display device of claim 13, wherein the first electrode and the second electrode are spaced apart from each other at a first gap on the same plane, and the first gap is smaller than a width of the light emitting element.

15. The display device of claim 13, further comprising a reflective layer between the first electrode and the second electrode on the substrate,
wherein the first electrode and the second electrode are on the same plane and spaced from each other at a first gap, and the first gap is wider than a width of the light emitting element.

16. The display device of claim 15, wherein the reflective layer overlaps the light emitting element, and a width of the reflective layer is greater than the width of the light emitting element.

17. The display device of claim 1, wherein a width of the organic pattern layer is greater than a width of the light emitting element.

18. The display device of claim 17, wherein the organic pattern layer covers a portion of the first electrode and the second electrode and fills a gap space between the first electrode and the second electrode.

19. A method of manufacturing display device comprising:
preparing a substrate on which a first electrode and a second electrode are located;
forming an organic pattern layer between the first electrode and the second electrode on the substrate;
disposing and fixing a light emitting element on the organic pattern layer;
forming a first via layer covering the light emitting element and having a plurality of connection holes; and
forming a first lower connection electrode connecting the first electrode and a first contact electrode located on the light emitting element through the plurality of connection holes and a second lower connection electrode connecting the second electrode and a second contact electrode located on the light emitting element on the first via layer;
forming a second via layer covering a portion of a side surface of the light emitting element on the first via layer; and
forming a first upper connection electrode connecting the first electrode and the first contact electrode and a second upper connection electrode connecting the second electrode and the second contact electrode on the second via layer.

20. The method of claim 19, further comprising:
forming a partition wall including a light blocking material on the second via layer;
forming a first wavelength conversion layer in an area corresponding to a first sub-pixel, forming a second wavelength conversion layer in an area corresponding to a second sub-pixel, and forming a light transmission layer in an area corresponding to a third sub-pixel from among the areas compartmentalized by the partition wall; and
forming a first color filter on the first wavelength conversion layer, forming a second color filter on the second wavelength conversion layer, and forming a third color filter on the light transmission layer.

21. A display device comprising:
a substrate;
a first electrode and a second electrode on the substrate and spaced from each other;
an organic pattern layer overlapping at least a portion of the first electrode and the second electrode;
a light emitting element on the organic pattern layer and having a first contact electrode and a second contact electrode on one surface;
a first via layer on top of the first electrode and the second electrode and exposing the first contact electrode and the second contact electrode of the light emitting element;
a first lower connection electrode electrically connecting the first electrode and the first contact electrode on the first via layer, and a second lower connection electrode electrically connecting the second electrode and the second contact electrode;
a second via layer on top of the first via layer;
a first upper connection electrode connecting the first electrode and the first contact electrode on the second via layer, and a second upper connection electrode connecting the second electrode and the second contact electrode.

22. A display device comprising:
a substrate;
a first electrode on the substrate;
an organic pattern layer partially overlapping the first electrode;
a light emitting element on the organic pattern layer and having at least one first contact electrode on one surface;
a first lower connection electrode on the first electrode and connecting the first electrode of the light emitting element to the first contact electrode;
a second lower connection electrode on a first contact area on the first electrode and connected to the first lower connection electrode in the first contact area, and a second contact area connected to the first lower connection electrode in the second contact area;
wherein the first electrode, the first lower connection electrode, and the second lower connection electrode overlap each other in the second contact area.
